(19) United States
(12) Patent Application Publication
(10) Pub. No.: US 2026/0229465 A1
(43) Pub. Date: Aug. 6, 2026

(54) APPARATUS FOR PRODUCING FUNCTIONAL FILM AND METHOD FOR PRODUCING FUNCTIONAL FILM

(71) Applicant: Konica Minolta, Inc., Tokyo (JP)

(72) Inventor: Kazunari TADA, Hachioji-shi, Tokyo (JP)

(21) Appl. No.: 19/151,105

(22) PCT Filed: Oct. 24, 2023
(86) PCT No.: PCT/JP2023/038346

§ 371 Date: Jul. 25, 2025

(30) Foreign Application Priority Data
Jan. 26, 2023 (JP) 2023-010048

(51) Int. Cl. H01J 37/32

(52) U.S. Cl. CPC H01J 37/32568; H01J 37/32834; H01J 2237/3345

(57) ABSTRACT

Disclosed is an apparatus that produces a functional film having an uneven structure, including a plasma electrode used for etching, wherein an area of the plasma electrode is in a range of 1000 to 100,000 cm².

### CROSS REFERENCE TO RELATED APPLICATIONS

This is the U.S. national stage of application No. PCT/JP2023/038346, filed Oct. 24, 2023. Priority under 35 U.S.C. § 119(a) and 35 U.S.C. § 365(b) is claimed from Japanese Application No. 2023-010048 filed Jan. 26, 2023, the disclosure of which is also incorporated herein by reference.

### TECHNICAL FIELD

The present invention relates to an apparatus for producing a functional film and a method for producing a functional film. In particular, the present invention relates to an apparatus for producing a functional film and the like capable of efficiently forming a fine uneven structure at a low cost while using an etching technique.

### BACKGROUND ART

As a method for forming a fine uneven structure at a low cost, an unevenness forming method using a sol-gel method is known. However, in the sol-gel method, the abrasion resistance is low and the practicality is poor. On the other hand, there is a method for forming fine unevenness by etching a hard inorganic substance. This method is resistant to abrasion but has a problem of high production cost.

On the other hand, there is a method for forming a fine uneven structure by an etching apparatus. A plasma electrode of a commonly used etching apparatus is optimized for a wafer having a size of 8 to 10 inches at the largest (e.g., see Patent Document 1). Then, etching is performed by exciting plasma at a frequency of 13.56 MHz, which is an industrial frequency, and introducing a reactive gas.

However, when an attempt is made to increase the size of the etching apparatus, in-plane distribution of etching becomes worse and a matching box for maintaining plasma becomes huge. Therefore, there is a problem that the cost increases.

For a small-sized chip such as a semiconductor, a large number of chips can be obtained. However, for a large-sized sample such as an optical component, the number of samples that can be processed is about 10. Therefore, the cost increases, and microfabrication has not been performed on a large component due to practical problems.

Even when a plurality of apparatuses is aligned for mass production, an increase in costs is inevitable. In addition, when a plasma electrode having a high frequency and a small size is used, an impact caused by plasma becomes large, which can damage a sample or a mask material. This also causes an increase in costs.

### CITATION LIST

### Patent Literature

Patent Document 1: JP 2002-176037A

### SUMMARY OF INVENTION

### Technical Problem

The present invention has been conceived in consideration of the above. The problem to be solved is to provide an apparatus for producing a functional film and a method for producing a functional film capable of efficiently forming a fine uneven structure at a low cost while using an etching technique.

### Solution to Problem

In order to solve the above-described problem, the present invention has found the importance of setting the area of a plasma electrode used for etching in a specific range in the process of studying the cause and the like of the above-described problem.

That is, the above-described problem according to the present invention is solved by the following means.
1. An apparatus that produces a functional film having an uneven structure, comprising a plasma electrode used for etching, wherein an area of the plasma electrode is in a range of 1000 to 100000 cm².
12. A method for producing the functional film having the uneven structure, comprising using the apparatus according to any one of items 1 to 11.

### BRIEF DESCRIPTION OF DRAWINGS

FIG. 1 This is a schematic side view of an apparatus for producing a functional film of the present invention.

FIG. 2 This is a plan view of a first RF electrode.

FIG. 3 This is a side view for explaining flows of an etching gas in FIG. 1.

FIG. 4 This is a cross-sectional schematic diagram illustrating an example of a basic configuration of a functional film according to the present invention.

FIG. 5 This is a cross-sectional schematic diagram illustrating an example of a basic configuration of the functional film according to the present invention.

FIG. 6 This is a diagram illustrating a method for calculating the average diameter of protruding portions of the uppermost step and is a screen illustrating an example of an operation of analyzing an image captured with an electron microscope.

FIG. 7 This is a diagram illustrating the method for calculating the average diameter of the protruding portions of the uppermost step and is a screen illustrating the example of an operation of analyzing the image captured with the electron microscope.

FIG. 8 This is a diagram illustrating the method for calculating the average diameter of the protruding portions of the uppermost step and is a screen illustrating the example of an operation of analyzing the image captured with the electron microscope.

FIG. 9 This is a diagram illustrating a method for calculating the percentage of the surface area of the protruding portions of the uppermost step and is a screen illustrating an example of an operation of analyzing an image captured with an electron microscope.

FIG. 10 This is a diagram illustrating the method for calculating the percentage of the surface area of the protruding portions of the uppermost step and is a screen illustrating the example of an operation of analyzing the image captured with the electron microscope.

FIG. 11A This is a diagram illustrating the method for calculating the percentage of the surface area of the protruding portions of the uppermost step and is a screen illustrating an image captured with an atomic force microscope and binarized data.

FIG. 11B This is a diagram illustrating the method for calculating the percentage of the surface area of the protruding portions of the uppermost step and is a screen illustrating the image captured with the atomic force microscope and binarized data.

FIG. 12A This is a diagram illustrating the method for calculating the percentage of the surface area of the protruding portions of the uppermost step and is a screen illustrating an example of an operation of analyzing the image captured with the atomic force microscope.

FIG. 12B This is a diagram illustrating the method for calculating the percentage of the surface area of the protruding portions of the uppermost step and is a screen illustrating the example of an operation of analyzing the image captured with the atomic force microscope.

FIG. 12C This is a diagram illustrating the method for calculating the percentage of the surface area of the protruding portions of the uppermost step and is a screen illustrating the example of an operation of analyzing the image captured with the atomic force microscope.

FIG. 13A This is a diagram illustrating the method for calculating the percentage of the surface area of the protruding portions of the uppermost step and is a screen illustrating the example of an operation of analyzing the image captured with the atomic force microscope.

FIG. 13B This is a diagram illustrating the method for calculating the percentage of the surface area of the protruding portions of the uppermost step and is a screen illustrating the example of an operation of analyzing the image captured with the atomic force microscope.

FIG. 13C This is a diagram illustrating the method for calculating the percentage of the surface area of the protruding portions of the uppermost step and is a screen illustrating the example of an operation of analyzing the image captured with the atomic force microscope.

FIG. 14A This is a diagram illustrating the method for calculating the percentage of the surface area of the protruding portions of the uppermost step and is a screen illustrating the example of an operation of analyzing the image captured with the atomic force microscope.

FIG. 14B This is a diagram illustrating the method for calculating the percentage of the surface area of the protruding portions of the uppermost step and is a screen illustrating the example of an operation of analyzing the image captured with the atomic force microscope.

FIG. 14C This is a diagram illustrating the method for calculating the percentage of the surface area of the protruding portions of the uppermost step and is a screen illustrating the example of an operation of analyzing the image captured with the atomic force microscope.

FIG. 15A This is a diagram illustrating the method for calculating the percentage of the surface area of the protruding portions of the uppermost step and is a screen illustrating the example of an operation of analyzing the image captured with the atomic force microscope.

FIG. 15B This is a diagram illustrating the method for calculating the percentage of the surface area of the protruding portions of the uppermost step and is a screen illustrating the example of an operation of analyzing the image captured with the atomic force microscope.

FIG. 16 This is a cross-sectional schematic diagram illustrating an example of a basic configuration of the functional film according to the present invention.

FIG. 17A This is a process diagram illustrating an example of a method for producing a functional film according to the present invention.

FIG. 17B This is a process diagram illustrating the example of the method for producing a functional film according to the present invention.

FIG. 17C This is a process diagram illustrating the example of the method for producing a functional film according to the present invention.

FIG. 17D This is a process diagram illustrating the example of the method for producing a functional film according to the present invention.

FIG. 17E This is a process diagram illustrating the example of the method for producing a functional film according to the present invention.

FIG. 17F This is a process diagram illustrating the example of the method for producing a functional film according to the present invention.

FIG. 17G This is a process diagram illustrating the example of the method for producing a functional film according to the present invention.

### DESCRIPTION OF EMBODIMENTS

According to the above-described means of the present invention, it is possible to provide an apparatus and a method for producing a functional film capable of efficiently forming a fine uneven structure at a low cost while using an etching technique.

Although the realization mechanism or action mechanism of the effects of the present invention is not clear, the present inventor infers the mechanism as follows.

As described above, the present inventor has found that it is necessary to satisfy the following conditions in order to efficiently form a fine uneven structure at a low cost.
(a) An etching apparatus capable of processing a large area is used.
(b) In order to process a large area, a frequency of 1 MHZ or less at which matching is easily performed is used.
(c) In order to reduce damage to a mask and increase the area, multi-stage plasma electrodes are used.
(d) In order to ensure uniform etching characteristics on the surfaces of the plasma electrodes, the plasma electrodes are electrically connected in parallel.
(e) In order to suppress generation of hydrogen fluoride (HF) gas and reduce damage to the mask material, the temperature rise of the plasma electrodes is suppressed.
(f) In order to suppress the temperature rise of the plasma electrodes at a low cost, a cooling (e.g., water-cooling) solvent is allowed to flow inside all of the plasma electrodes.
(g) In order to prevent corrosion of a chamber due to the generation of hydrogen fluoride (HF) gas, an inner wall of the chamber and components are coated with a film made of aluminum or calcium, which forms a stable fluoride.
(h) In order to identify the risk of the generation of hydrogen fluoride (HF) gas due to an increase in size of the apparatus, a hydrogen fluoride (HF) gas detector tube is mounted in the chamber.

In order to satisfy the above-described conditions, it was necessary to set the areas of the plasma electrodes used for etching in the range of 1000 to 100000 cm².

By setting the areas of the plasma electrodes in the above range, an etching technique can be used for a large area. Therefore, a fine uneven structure formed by the etching has high abrasion resistance and can be efficiently formed at a low cost.

An apparatus for producing a functional film of the present invention is an apparatus for producing a functional film having an uneven structure, including plasma electrodes used for etching, wherein the areas of the plasma electrodes are in the range of 1000 to 100000 cm².

The above-described features are technical features common to or corresponding to the following embodiment.

As an embodiment of the present invention, it is preferable to perform etching by applying a power with a frequency in the range of 0.1 kHz to 1 MHz to the plasma electrodes from the viewpoint that costs can be reduced.

It is preferable that the apparatus includes at least two pairs of the plasma electrodes from the viewpoint that the areas of the plasma electrodes can be easily increased.

It is preferable that at least two pairs of the plasma electrodes are electrically connected in parallel from the viewpoint that plasma is uniformly generated and a functional film having a fine uneven structure can be formed.

It is preferable that the apparatus includes a mechanism that maintains the plasma electrodes at 45° C. or lower from the viewpoint that etching can be performed without decreasing the etching rate. This also makes it possible to prevent the temperature of the plasma electrodes from becoming high, thus preventing generation of hydrofluoric acid gas.

It is preferable to have a cooling solvent circulating through the plasma electrodes from the viewpoint that costs can be reduced as compared with cooling with a gas.

It is preferable that the apparatus includes a chamber in which the plasma electrodes are disposed, and the chamber is uniformly filled with an etching gas from the viewpoint that the rate of the etching gas can be made uniform.

It is preferable that 50% or more of the surface area of an inner wall of the chamber and a member to be disposed in the chamber is coated with a film made of aluminum or calcium. This prevents harmful gas from being attached to the inner wall of the chamber and the member to be disposed in the chamber. This also renders harmful gas harmless.

By providing a detector for detecting the concentration of hydrogen fluoride (HF) gas in the chamber, it is possible to prevent a door from being opened when the concentration of hydrogen fluoride gas is high. Therefore, providing the detector is preferable from the viewpoint of safety.

It is preferable that the apparatus includes a chamber in which the plasma electrodes are disposed, the chamber is provided with an introduction port for introducing a gas and an exhaust port for exhausting the gas, and the introduction port and the exhaust port are disposed at opposite positions across the plasma electrodes. This allows the chamber to be uniformly filled with an etching gas.

A method for producing a functional film of the present invention is a method for producing a functional film having an uneven structure with randomness without regularity and uses the apparatus for producing a functional film of the present invention.

Hereinafter, the present invention, constituent elements of the present invention, and embodiments and modes for carrying out the present invention will be described. In the present description, “to” between two numerical values is used to indicate a range of values including the two numerical values as a lower limit value and an upper limit value.

### [Apparatus for Producing Functional Film of the Present Invention]

The apparatus for producing a functional film of the present invention is an apparatus for producing a functional film having an uneven structure with randomness without regularity and includes plasma electrodes used for etching, wherein the areas of the plasma electrodes are in the range of 1000 to 100000 cm².

In the present invention, the “areas of the plasma electrodes” refers to the total area of a portion on which an object to be etched is placed. Specific examples of the object include a substrate on which a film has been formed.

It is preferable that the areas of the plasma electrodes are in the range of 4000 to 20000 cm².

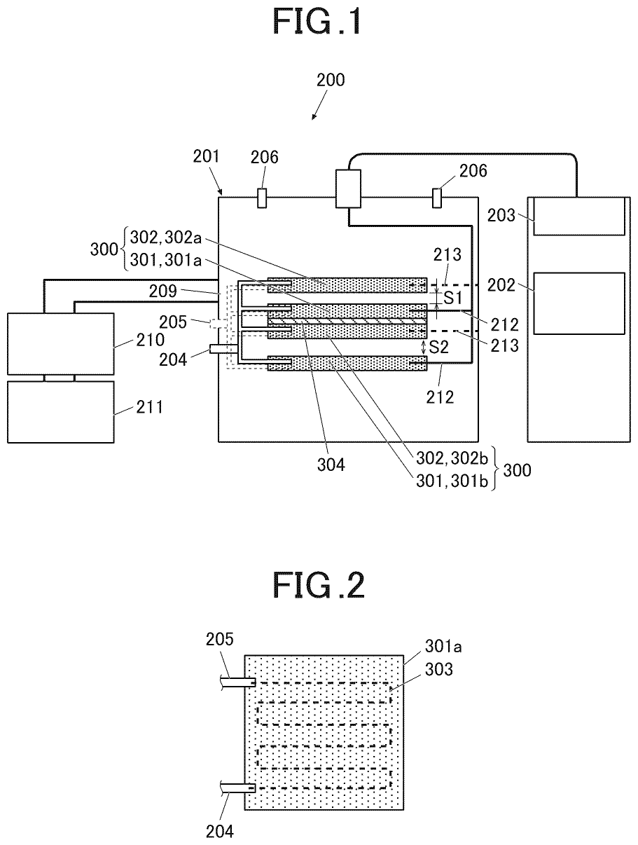

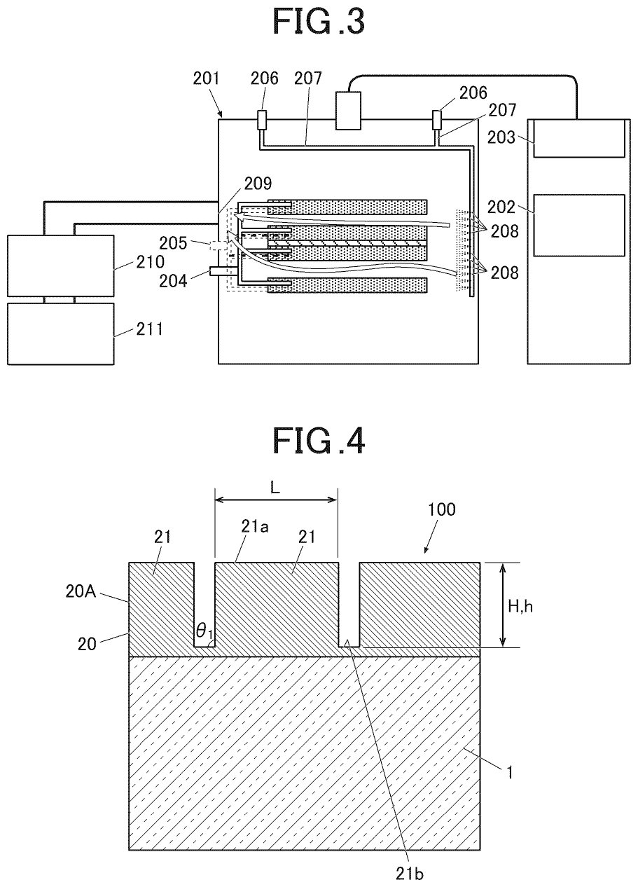

FIG. 1 is a schematic side view of the apparatus for producing a functional film of the present invention. FIG. 2 is a plan view of a first RF electrode. FIG. 3 is a diagram for explaining flows of an etching gas in FIG. 1.

As illustrated in FIG. 1, a production apparatus 200 includes a chamber 201 and plasma electrodes 300 disposed in the chamber 201.

The plasma electrodes 300 include an RF electrode 301 and a ground electrode 302.

The RF electrode 301 is connected to an RF power source (high-frequency power source) 203 via a wiring 212 and a matching box 202. The RF power source 203 alone applies power with a frequency in the range of 0.1 kHz to 1 MHz to the plasma electrodes 300. That is, the power is applied to the plasma electrodes 300 by only one RF power source 203. The cost can be reduced by having the RF power source 203 alone apply the power to the plasma electrodes 300.

The ground electrode 302 is connected to the chamber 201, which is grounded, via a wiring 213 and is at a potential of 0 (zero).

Note that the chamber 201 itself is grounded and is at a potential of 0.

Such one RF electrode 301 and one ground electrode 302 form a pair. In FIG. 1, two pairs of the RF electrode 301 and the ground electrode 302 are provided. That is, in the chamber 201, a first ground electrode 302a, a first RF electrode 301a, a second ground electrode 302b, and a second RF electrode 301b are disposed in this order from top to bottom, facing each other. Then, the first RF electrode 301a and the second RF electrode 301b are electrically connected in parallel. The first ground electrode 302a and the second ground electrode 302b are electrically connected in parallel.

An insulating plate-like member 304 is disposed between the first RF electrode 301a and the second ground electrode 302b.

Examples of the insulating plate-like member 304 include a Teflon (registered trademark) plate. Providing an insulating plate-like member in this manner prevents a short circuit between the first RF electrode 301a and the second ground electrode 302b. Note that even without providing the insulating plate-like member 304, the first RF electrode 301a and the second ground electrode 302b may be disposed at a predetermined spacing so as not to contact each other. However, it is preferable to provide the insulating plate-like member 304 from the viewpoint of saving space in the chamber 301.

The areas of portions of the two pairs on which samples are placed, that is, the areas of the first RF electrode 301a and the second RF electrode 301b in FIG. 1 correspond to the placing area, which is referred to as the total area. The total area is in the range of 1000 to 100000 cm². The total area is preferably in the range of 4000 to 20000 cm².

Furthermore, a cooling mechanism that maintains the electrodes at 45° C. or lower is disposed inside the first ground electrode 302a and RF electrode 301a, and the second ground electrode 302b and RF electrode 301b.

As the cooling mechanism, for example, as illustrated in FIG. 2, a meandering pipe 303 is embedded in the first RF electrode 301a. The pipe is preferably made of copper.

In addition to the first RF electrode 301a, a meandering pipe 303 is also embedded in each of the other electrodes.

One end of each pipe 303 serves as an inlet through which a cooling solvent flows in and is connected to an inlet pipe 204. The other end of the pipe 303 serves as an outlet through which the cooling solvent flowing through the pipe 303 flows out and is connected to an outlet pipe 205.

The cooling solvent may be supplied in series connection to the four electrodes in series or may be supplied in parallel connection to the respective electrodes. The parallel connection is more preferable than the series connection from the viewpoint that the water pressure can be kept low.

The inlet pipes 204 and the outlet pipes 205 connected to the respective pipes 303 of the respective electrodes are collected into a single inlet pipe and a single outlet pipe, respectively. Each of the single inlet pipe and the single outlet pipe is drawn out of the chamber 201 from a predetermined position of the chamber 201. Then, the inlet pipe 204 and the outlet pipe 205 are connected to a chiller device (not shown) or the like for circulating the cooling solvent.

Each electrode is cooled by circulating the cooling solvent through the pipe 303 formed as described above. Note that examples of the cooling solvent include water, an organic solvent (e.g., methanol, ethanol, and ethylene glycol), a mixed solvent of water and the organic solvent, and liquid nitrogen.

The temperature of the cooling solvent is, for example, preferably in the range of 5 to 25° C. for water.

By providing the cooling mechanism, the plasma electrodes can be maintained at 45° C. or lower. By maintaining the plasma electrodes at 45° C. or lower, etching can be performed without decreasing the etching rate. Furthermore, this makes it possible to prevent the temperature of the plasma electrodes from becoming high, thus preventing the generation of hydrofluoric acid gas.

The temperature of each plasma electrode can be measured, for example, by using a Thermochron Type G (manufactured by KN Laboratories, Inc.) to monitor the temperature of the electrode on which plasma is generated during a process under vacuum.

A spacing S1 between the first ground electrode 302a and the first RF electrode 301a is preferably in the range of 2 to 20 cm and is preferably in the range of 5 to 10 cm. Here, the spacing S1 refers to the shortest distance between the surfaces of the first ground electrode 302a and the first RF electrode 301a that face each other.

Furthermore, a spacing S2 between the second ground electrode 302b and the second RF electrode 301b is preferably in the range of 2 to 20 cm and is preferably in the range of 5 to 10 cm. The spacing S2 refers to the shortest distance between the surfaces of the second ground electrode 302b and the second RF electrode 301b that face each other. By setting the spacing S1 and the spacing S2 in the above ranges, it becomes easier to take in and out a sample while effectively using the space of the apparatus, and the plasma becomes stabilized.

Note that the disposition order of the electrodes is not limited to that illustrated in FIG. 1 but may be changed as appropriate. Further, although the electrodes are connected in parallel, they may be connected in series. That is, the first RF electrode 301a and the second RF electrode 301b may be electrically connected in series, and the first ground electrode 302a and the second ground electrode 302b may be electrically connected.

In particular, it is preferable that the electrodes are connected in parallel because the plasma density becomes uniform.

As illustrated in FIG. 3, two etching gas introduction parts 206 are disposed on an upper surface of the chamber 201. A gas introduction pipe 207 is connected to each of the etching gas introduction parts 206. One end of the gas introduction pipe 207 is connected to the gas introduction part 206. The other end of the gas introduction pipe 207 extends, inside the chamber 201, from an upper portion to a sidewall of the chamber 201. Gas is introduced into the chamber 201 from the other end (introduction ports 208) of the gas introduction pipe 207 disposed on the sidewall.

The gas introduction pipe 207 has a large number of introduction ports 208 at the other end. Gas is sprayed from the introduction ports in a shower-like manner. In this way, the entire chamber 201 is uniformly filled with the gas.

In addition, an exhaust port 209 for exhausting a gas is disposed at a position on the sidewall of the chamber 201, facing the other end (introduction ports 208) of the gas introduction pipe 207. That is, the other end (introduction ports 208) of the gas introduction pipe 207 and the exhaust port 209 are disposed at opposite positions across the plasma electrodes 300. Specifically, when the chamber 201 is viewed in plan view, the exhaust port 209 and the introduction ports 208 are positioned 180 degrees apart from each other, with the plasma electrodes 300 at the center.

The exhaust port 209 is connected to a rotary pump 211 via a mechanical booster pump 210. Therefore, the mechanical booster pump 210 and the rotary pump 211 are driven to generate predetermined pressure in the chamber 201.

The initial degree of vacuum in the chamber 201 is preferably in the range of 1 to 20 Pa, for example. In addition, the temperature of the chamber 201 is preferably in the range of 5 to 45° C.

As the etching gas, for example, Ar, O₂, N₂, CHF₃, CF₄, COF₂, SF₆ or the like is preferably used, and CHF₃ is particularly preferably used.

In addition, the flow rate of the etching gas is preferably in the range of 5 to 100 sccm.

The gas pressure of the etching gas is not particularly limited but is preferably in the range of 0.1 to 20 Pa, and more preferably in the range of 5 to 15 Pa, from the viewpoint of the processing speed and the like.

In the production apparatus 200 described above, the etching gas is supplied into the chamber 201, and a predetermined voltage is applied from the RF power source to the first and second RF electrodes 301a and 301b, whereby the etching gas is turned into plasma. Then, plasma ions are generated between the first RF electrode 301a and the first ground electrode 302a and between the second RF electrode 301b and the second ground electrode 302b. Then, objects to be etched (e.g., an inorganic layer formed on a substrate) respectively placed on the first RF electrode 301a and the second RF electrode 301b can be etched by the plasma ions.

Arrows in FIG. 3 indicate flows of the etching gas introduced from the introduction ports 208.

Although the gas introduction pipe 207, the introduction ports 208, and the exhaust port 209 illustrated in FIG. 3 are not illustrated in FIG. 1 for convenience of illustration, the gas introduction pipe 207, the introduction ports 208, and the exhaust port 209 are also provided in FIG. 1. Furthermore, although the wiring 212 and the wiring 213 illustrated in FIG. 1 are not illustrated in FIG. 3 for convenience of illustration, the wiring 212 and the wiring 213 are also provided in FIG. 3.

It is preferable that 50% or more of the surface area of an inner wall of the chamber 201 and the members to be disposed in the chamber 201 is coated with a film made of aluminum or calcium.

Specific examples of the members to be disposed in the chamber 201 include the inlet pipe 204, the outlet pipe 205, the gas introduction pipe 207, the wiring 212, and the wiring 213.

When etching is performed using a fluorocarbon-based gas, a fluoride is generated by fluorine. When the fluoride is unstable, the fluoride gradually reacts with moisture in the air and turns into a hydrogen fluoride gas. When the chamber interior is made of stainless steel (SUS), its main components, such as iron and chromium, form unstable fluorides, which become a source of hydrogen fluoride. Therefore, for example, a plate material of a calcium silicate plate (A&A Material Corporation) is used as an attachment preventive plate in the chamber made of stainless steel, or the inner wall of the chamber and the members inside the chamber are coated with aluminum using an Alpha Aluminum Coating Spray (TRUSCO NAKAYAMA CORPORATION), which is a rust preventive coating, so as to be rust-preventive. This prevents attachment of fluorine due to fluorination of SUS.

A detector GD-70D (RIKEN KEIKI Co., Ltd.) for detecting the concentration of the hydrogen fluoride gas is provided in the chamber 201. Since the detector constantly detects the concentration of the hydrogen fluoride gas in the chamber 201, it is possible to prevent the concentration of the hydrogen fluoride gas from becoming high. When the concentration exceeds 0.5 ppm, which is the control concentration set by the Industrial Safety and Health Act, the hydrogen fluoride gas is automatically discharged by the vacuum pumps. In addition, the chamber is configured to apply an interlock so that a door can be opened safely when the concentration becomes 0.5 ppm or less.

### [Functional Film]

Next, an example of the functional film produced using the apparatus for producing a functional film of the present invention will be described. However, the functional film produced using the production apparatus of the present invention is not limited thereto. The functional film according to the present invention is not particularly limited as long as the film is a film having an uneven structure formed by, for example, etching.

The functional film has an uneven structure. It is preferable that the uneven structure has randomness without regularity.

In the present invention, the “uneven structure” refers to a structure having a plurality of fine protruding and recessed shapes capable of exhibiting a water-repellent effect. In addition, the “uneven structure” refers to an uneven structure in which at least the average height of protruding portions is 1 μm or less when the lowermost surface of recessed portions is used as the reference. In other words, the “uneven structure” refers to an uneven structure in which the average depth of the recessed portions is 1 μm or less.

A layer having the fine uneven structure is referred to as an “uneven layer”.

Furthermore, in the functional film according to the present invention, it is preferable that, in a vertical cross-sectional shape in a film thickness direction, a plurality of protruding portions constituting the fine uneven structure are formed in a staircase shape of one step or a plurality of steps.

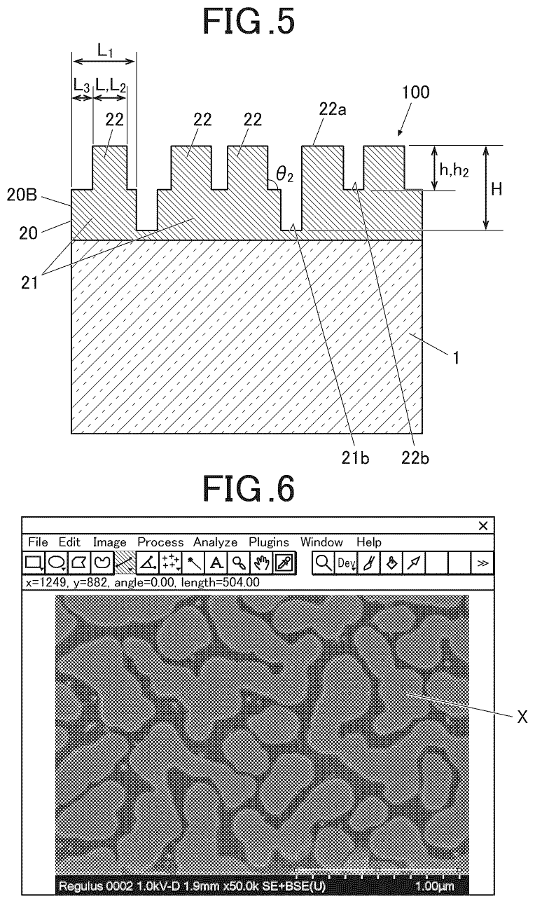

Here, the “staircase of one step or a plurality of steps” of the protruding portions means that the distance of a substantially horizontal planar portion is equal to or greater than 10 nm. The distance of a substantially horizontal planar portion is the average diameter L in FIG. 4 for one step and L₃ in FIG. 5 for the plurality of steps. The distance of a substantially horizontal planar portion is preferably equal to or greater than 30 nm and particularly preferably in the range of 50 to 500 nm. In addition, the angle formed between the substantially horizontal planar portion of the staircase and the vertical direction is in the range of 60 to 140 degrees. The angle formed between the substantially horizontal planar portion of the staircase and the vertical direction is the angle θ₁ in FIG. 4 for one step and the angle θ₂ in FIG. 5 for the plurality of steps. A preferable range of the angle is in the range of 70 to 120 degrees.

Further, in the case of the multi-step structure, in detail, it is preferable that any one of the following conditions (1) to (3) is satisfied by at least one of the protruding portions. In particular, it is more preferable that all of the following conditions (1) to (3) are satisfied.
(1) In the vertical cross section of the fine uneven structure, for the protruding portions of adjacent steps, the average height (for example, h₂ in FIG. 5) of the protruding portions of the upper step is equal to or greater than 10 nm.
(2) When the fine uneven structure is viewed from above, for the protruding portions of adjacent steps, the difference between the average diameter of the protruding portions of the upper step (for example, L₂ in FIG. 5) and the average diameter of the protruding portions of the lower step (for example, L₁ in FIG. 5) is equal to or greater than 10 nm.
(3) When the fine uneven structure is viewed from above, for the protruding portions of adjacent steps, the difference between the percentage of the surface area of the protruding portions of the upper step and the percentage of the surface area of the protruding portions of the lower step is equal to or greater than 5%.

Note that in (1), the average height h₂ is preferably 30 nm or more, particularly preferably in the range of 50 to 500 nm. Furthermore in (3), it is more preferable that the difference in the percentage of the surface area is 10% or more.

Measurement can be performed by general cross-sectional SEM observation or AFM observation, and it is assumed that the average value of measurements at 10 or more locations satisfies the above-mentioned conditions.

The “lowermost surface of the protruding portions of the lowermost step” refers to a surface included in the same reference plane as the “lowermost surface of the recessed portions” described above.

On the other hand, a “lower surface of a protruding portion of the uppermost step” described later refers to a surface included in the same plane as the lowermost surface of the recessed portions adjacent to the protruding portion of the uppermost step.

The above definitions will be described in detail in the description of shape observation using an atomic force microscope (AFM).

The definitions of the “average height of the protruding portions”, the “average diameter of the protruding portions”, and the “percentage of the surface area of the protruding portions” will also be described later.

FIG. 4 and FIG. 5 are cross-sectional schematic diagrams, each illustrating an example of a basic configuration of the functional film according to the present invention.

As illustrated in FIG. 4 and FIG. 5, a functional film 100 is formed on, for example, a base material 1 described later. The functional film 100 contains an inorganic substance as its main component and has a fine uneven structure 20A or 20B on its surface. Then, in a vertical cross-sectional shape in the film thickness direction, protruding portions with the fine uneven structure 20A or 20B are formed in a staircase shape of one step or a plurality of steps.

In the present invention, determination of whether the “protruding portions with the fine uneven structure are formed in a staircase shape of one step or a plurality of steps” and confirmation of the shape can be performed as follows.

Examples of the determination and the confirmation include a method for observing a cross-sectional shape of a three dimensional image obtained by measurement using an atomic force microscope (AFM). Alternatively, the determination and the confirmation can be performed by a method for observing a cross section of the functional film with an electron microscope, or a combination of both methods under the conditions described later.

Specifically, FIG. 4 is a cross-sectional schematic diagram illustrating a functional film including protruding portions of a one-step shape. FIG. 5 is a cross-sectional schematic diagram illustrating a functional film including protruding portions of a two-step shape. In FIG. 4, the functional film 100 having the fine uneven structure 20A including a plurality of protruding portions of a one-step shape (protruding portions 21 of the first step) containing an inorganic substance is formed on the base material 1. A layer having the fine uneven structure 20A is referred to as an uneven layer 20.

Furthermore, in FIG. 5, the functional film 100 having the fine uneven structure 20B including a plurality of protruding portions of a two-step shape containing an inorganic substance is formed on the base material 1. That is, the fine uneven structure 20B includes the protruding portions 21 of the first step formed on the substrate 1 and protruding portions 22 of the second step formed on the protruding portions 21 of the first step. A layer having the fine uneven structure 20B is referred to as an uneven layer 20.

In the present application, the “protruding portions 21 of the first step” refers to protruding portions formed on the base material 1. The “protruding portions 22 of the second step” refers to protruding portions formed on the protruding portions 21 of the first step.

The functional film according to the present invention preferably contains an inorganic substance.

In the present invention, the following formula (I) is preferably satisfied, where X represents the Mohs hardness of the inorganic substance contained in the functional film as its main component, and Y represents the number of steps of the protruding portions. Formula (I): 10≤X×Y

$$More preferably , 14 \leq X \times Y \leq 39 .$$

In other words, when the number of steps of the protruding portions is one, that is, the protruding portions has a one-step shape, an inorganic substance having a Mohs hardness of 10 or higher is to be contained. When the number of steps is two or more, it is sufficient that an inorganic substance having a Mohs hardness of 5 or higher is contained.

### <Mohs Hardness>

As the Mohs hardness in the present invention, a modified Mohs hardness modified into 15 levels is used.

The Mohs hardness of typical inorganic substances is listed below.

TABLE I

| MODIFIED MOHS | STANDARD MINERAL | | HARDNESS |
|---|---|---|---|
| HARDNESS | NAME | CHEMICAL COMPOSITION | (HK) |
| 8 | QUARTZ (CRYSTAL) | SiO₂ | 820 |
| 9 | TOPAZ | Al₂(F,OH)₂(SiO₄) | 1340 |
| 10 | GARNET | (Ma,Ca,Fe)₃(Al,Cr,Fe)₂(SiO₄)₃ | 1360 |
| 11 | FUSED ZIRCONIA | ZrO₂ | (1160) |
| | TANTALUM CARBIDE | TaC | 2000 |
| 12 | CORUNDUM | Al₂O₃ | (2100) |
| | TUNGSTEN CARBIDE | WC | 1880 |
| 13 | SILICON CARBIDE | SiC | 2480 |
| 14 | BORON CARBIDE | B₄C | 2750 |
| 15 | DIAMOND | C | 7000 |

The term “containing an inorganic substance as its main component” as used in the present invention means that the ratio of the inorganic substance to all the components constituting the functional film is 80% by mass or more. Preferably, the ratio is 90% by mass or more and 99.9% by mass or less, particularly preferably 97% by mass or more and 100% by mass or less.

The inorganic substance is not particularly limited as long as Formula (I) is satisfied, but it is preferable that at least an inorganic substance having a Mohs hardness of 9 or higher is contained. Further, it is preferable that an inorganic substance having a Mohs hardness of 13 or higher is contained.

When the protruding portions with the fine uneven structure have a one-step shape (Y=1), it is necessary that an inorganic substance having a Mohs hardness of 10 or higher is contained in order to satisfy the formula (I). Further, when the protruding portions with the fine uneven structure have a two- or more-step shape, an inorganic substance having a Mohs hardness of 5 or lower may be contained.

Examples of the inorganic substance having a Mohs hardness of 9 or higher include Al₂(F, OH)₂(SiO₄), (Mg, Ca, Fe)₃(Al, Cr, Fe)₂(SiO₄)₃, ZrO₂, TaC, Al₂O₃, WC, SiC, B₄C, C, SiOC, and SiCN. In particular, Al₂O₃, SiC, SiOC, or SiCN is preferably used.

Here, when the protruding portions have a one-step shape, SiC, SiOC, or SiCN is preferably used. The functional film using SiC, SiOC, or SiCN is suitably used for, for example, an inkjet head or a mold.

In addition, when the protruding portions have a two- or more-step shape (Y≥2), transparent SiO₂ is preferably used. Specifically, such a functional film is suitably used for, for example, an optical device. A material containing Ge as its main component, such as chalcogenide, Si, or the like is also suitably used for an optical device for infrared.

In the present invention, it is preferable that the number of steps (integer Y) of the protruding portions is 2, that is, the protruding portions have a two-step shape.

### <Shape and Randomness of Protruding Portions>

As for the shape of the protruding portions in the fine uneven structure according to the present invention, it is an essential or suitable condition that, for example, the height, the size, and the like fall within condition ranges as described later.

However, when the protruding portions in the fine uneven structure are observed as a whole, it is preferable that the relative positions and shapes of the plurality of protruding portions exhibit randomness without regularity in terms of identity or periodicity within the condition ranges described later. With such randomness, light diffraction can be prevented.

The term “randomness” as used in the present invention refers to a state in which randomness or unpredictability is recognized in which there is no regularity, such as overall identity or periodicity, in terms of the relative positions and shapes of the protruding portions, under a condition on the assumption that the formation of the protruding portions in the fine uneven structure is controlled within the condition ranges with respect to the shape described later. Furthermore, the “randomness” refers to a state in which no diffracted light is generated.

In addition, it is more preferable that at least a portion of the plurality of protruding portions have a mesh-like structure when the fine uneven structure is viewed from above, from the viewpoint of achieving both the abrasion resistance and the super water repellency.

Here, the phrase “at least a portion of the protruding portions have a mesh-like structure” refers to a state where, when viewed from above, the protruding portions are continuously connected to each other, with no unconnected portions. That is, it refers to a network-like structure in which the major axes of the protruding portions cannot be defined.

### <Total Average Height>

In a vertical cross section in the film thickness direction of the fine uneven structure, the average height from the lowermost surface of the protruding portions of the lowermost step to the uppermost surface of the protruding portions of the uppermost step is preferably 1 μm or less.

In the present invention, the “average height from the lowermost surface of the protruding portions of the lowermost step to the uppermost surface of the protruding portions of the uppermost step (also referred to as “total average height H”)” refers to, for example, a total etching depth in a vertical cross section (cross section in the thickness direction) of the fine uneven structure when recessed portions are formed by etching a formed inorganic layer.

To be specific, when the protruding portions have a two-step shape, as illustrated in FIG. 5, the height H refers to the distance from the lowermost surface (base end surface) 21b of the protruding portions 21 of the first step (lowermost step) to the uppermost surface (topmost surface) 22a of the protruding portions 22 of the second step (uppermost step).

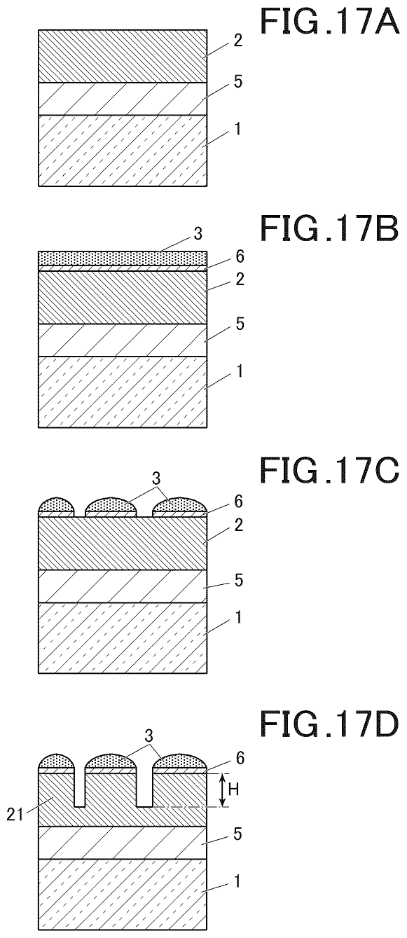

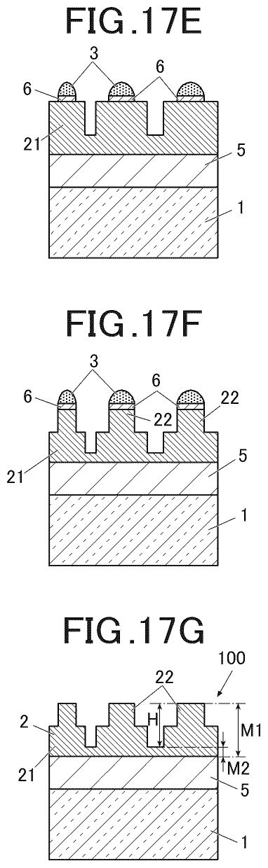

Therefore, as illustrated in FIG. 17A to FIG. 17G, the height H refers to the distance of a portion obtained by subtracting the thickness M2 of the unetched inorganic layer 2 from the total thickness M1 of the inorganic layer 2 formed by a method for producing the functional film 100.

Further, when the protruding portions have a one-step shape, as illustrated in FIG. 4, the height H refers to the distance from the lowermost surface (base end surface) 21b to the uppermost surface (topmost surface) 21a of the protruding portions 21 of the uppermost step. In the same manner as described above, the height H refers to the distance of a portion obtained by subtracting the thickness M2 of the unetched inorganic layer 2 from the total thickness M1 of the inorganic layer 2 formed by a method for producing the functional film.

The total average height H is 1 μm or less and preferably in the range of 0.05 to 0.25 μm.

The total average height H can be calculated by an image analysis method using an atomic force microscope (AFM) as described later.

In order to set the total average height to 1 μm or less, for example, the thickness of the inorganic layer to be formed, and the thickness, the film formation temperature, the etching time, and the like of a metal mask may be controlled as described below.

<Average Diameter, Percentage of Surface Area, and Average Height of Protruding Portions of Uppermost Step>

It is preferable that, when the fine uneven structure is viewed from above, the average diameter of the protruding portions of the uppermost step is in the range of 10 to 500 nm.

In addition, it is preferable that the percentage of the surface area of the protruding portions of the uppermost step relative to the surface area of the entire fine uneven structure is in the range of 30 to 70%.

Further, in a vertical cross section of the fine uneven structure, the average height from the lower surfaces of the protruding portions of the uppermost step to the uppermost surface of the protruding portions of the uppermost step is preferably in the range of 10 to 250 nm.

By setting the average diameter, the percentage of the surface area, and the average height in the above ranges, both the abrasion resistance and the super water repellency can be achieved.

The average diameter of the protruding portions of the uppermost step is preferably in the range of 10 to 500 nm, and more preferably in the range of 50 to 200 nm.

The “average diameter of the protruding portions of the uppermost step” refers to the average diameter of the protruding portions of the uppermost step when the fine uneven structure is viewed from above, that is, when an image of the entire fine uneven structure is captured from above with an electron microscope and the image is observed.

For example, as illustrated in FIG. 4, for the fine uneven structure 20A including the protruding portions of a one-step shape, the average diameter refers to the average diameter L of the protruding portions 21 of the first step (uppermost step). In addition, as illustrated in FIG. 5, for the fine uneven structure 20B including the protruding portions of a two-step shape, the average diameter refers to the average diameter L of the protruding portions 22 of the second step (uppermost step).

The average diameter L of the protruding portions of the uppermost step can be calculated using an image processing free software for an image captured with an electron microscope as described later. An example of the image processing free software includes “ImageJ (ImageJ 1.32S, created by Wayne Rasband)”.

The percentage of the surface area of the protruding portions of the uppermost step relative to the total surface area of the entire fine uneven structure is preferably in the range of 30 to 70%, and more preferably in the range of 30 to 55%.

The “percentage of the surface area of the protruding portions of the uppermost step relative to the surface area of the entire fine uneven structure when the fine uneven structure is viewed from above” is the percentage of the surface area of the protruding portions of the uppermost step relative to the surface area of the entire fine uneven structure when the fine uneven structure is viewed from above, that is, when an image of the entire fine uneven structure is captured from above with an electron microscope and the image is observed. Here, the “entire fine uneven structure” refers to the entire structure including all of the protruding portions and the recessed portions.

The percentage of the surface area of the protruding portions of the uppermost step can be calculated using image processing free software for an image captured with an electron microscope as described later.

An example of the image processing free software includes “ImageJ (ImageJ 1.32S, created by Wayne Rasband)”.

In addition, the percentage may be calculated by measuring image data of the fine uneven structure using an AFM and binarizing the image measured by the AFM using software manufactured by BRUKER.

When the AFM probe does not enter a narrow groove (recessed portion), data is obtained as if the protruding portions had a one-step shape, even when the protruding portions have a two-step shape. Therefore, it is preferable to select a super sharp cantilever or a high aspect ratio cantilever whenever possible.

Further, the average height from the lower surfaces to the uppermost surface of the protruding portions of the uppermost step is preferably in the range of 10 to 250 nm, and more preferably in the range of 30 to 200 nm for a one-step. For a two-step, the average height is preferably in the range of 10 to 150 nm, more preferably in the range of 30 to 100 nm. For a three-step, the average height is preferably in the range of 10 to 100 nm, more preferably in the range of 20 to 50 nm.

For example, as illustrated in FIG. 5, for the fine uneven structure 20B including the protruding portions of a two-step shape, the “average height from the lower surfaces to the uppermost surface of the protruding portions of the uppermost step (also referred to as “average height h”)” refers to the distance h from the lowermost surface 22b of the protruding portions 22 of the second step (the uppermost step) to the uppermost surface (topmost surface) 22a of the protruding portions 22 of the second step in the vertical cross section (cross section in the thickness direction) of the fine uneven structure.

For the fine uneven structure 20A including the protruding portions of a one-step shape, the average height refers to the distance h from the lowermost surface 21b to the uppermost surface (topmost surface) 21a of the protruding portions 21 of the first step (uppermost step). Therefore, it is the same as the total average height H described above.

The average height h from the lower surfaces to the uppermost surface of the protruding portions of the uppermost step can be calculated by using an atomic force microscope as described later, or by observing a cross section of the protruding portions with an SEM.

In order to set the average diameter L, the percentage of the surface area, and the average height h of the protruding portions of the uppermost step in the above ranges, the thickness of the inorganic layer to be formed may be controlled. In addition, as will be described later, the thickness, the film formation temperature, the etching time, and the like of a metal mask may be controlled.

Furthermore, it is preferable from the viewpoint of durability that, when the fine uneven structure is viewed from above, the ratio of the major axis diameter to the minor axis diameter (major axis diameter/minor axis diameter) of at least a portion of the protruding portions among the plurality of protruding portions is 2 or more. The ratio is more preferably 5 or more. Specifically, for example, when viewed from above, the shape is preferably L-shaped rather than completely circular.

Here, the “major axis diameter of a protruding portion” refers to the diameter of the minimum circumscribed circle C1 drawn on the protruding portion when the fine uneven structure is observed with an SEM in a “method for calculating the average diameter of the protruding portions of the uppermost step” described below. The “minor axis diameter of a protruding portion” refers to the diameter of the maximum inscribed circle C2 drawn on the protruding portion.

In addition, the protruding portions of which the ratio of the major axis diameter to the minor axis diameter is 2 or more may be the protruding portions of the first step or the protruding portions of the second or higher step. It is preferable that any of the protruding portions of the first step or the protruding portions of the second or higher step include protruding portions having such a ratio, because the durability is excellent. In practice, it is preferable that the protruding portions of the first step include protruding portions having such a ratio.

Furthermore, when the fine uneven structure is viewed from above, it is preferable that the average diameter of the protruding portions of the uppermost step is smaller than the average diameter of the protruding portions of a step lower than the uppermost step. This allows for both the super water repellency and the abrasion resistance.

For example, as illustrated in FIG. 5, for the fine uneven structure 20B including the protruding portions of a two-step shape, the average diameter L of the protruding portions 22 of the uppermost step (second step) is preferably in the range of 10 to 500 nm as described above. The average diameter of the protruding portions 21 of a lower step (first step) is preferably in the range of 100 to 1000 nm.

In addition, for a three-step shape, the average diameter of the protruding portions of the uppermost step (third step) is preferably in the range of 10 to 500 nm as described above. The average diameter of the protruding portions in the middle (of the second step) is preferably in the range of 100 to 600 nm. The average diameter of the protruding portion of the lowermost step (first step) is preferably in the range of 100 to 1000 nm.

The average diameter of the protruding portions of a lower step can be calculated by the above-described method before the protruding portions of an upper step are formed.

The plurality of protruding portions 21 and the plurality of protruding portions 22 may be formed with regularity but are preferably formed with randomness as described above. By forming the protruding portions 21 and 22 with randomness, light diffraction can be prevented when the functional film is applied to an optical device.

### <Method for Calculating Average Diameter of Protruding Portions of Uppermost Step>

The average diameter of the protruding portions of the uppermost step can be calculated by capturing an image of the fine uneven structure with a scanning electron microscope (SEM) or a transmission electron microscope (TEM) and using image processing free software for the captured image. An example of the image processing free software includes “ImageJ (ImageJ 1.32S, created by Wayne Rasband)”.

Hereinafter, a procedure of image analysis using an electron micrograph (SEM) will be described.
1) Download the free software ImageJ.
2) Perform image processing using the following procedure with the initial settings.
3) Load into a personal computer using the free software ImageJ a SEM image of the surface of the fine uneven structure captured in advance at a magnification of 30,000 times or more using a scanning electron microscope.
4) Correlate the number of pixels with the physical length. For example, in FIG. 6, 1 μm is equal to 504 pixels.
5) Measure the major axis diameter.

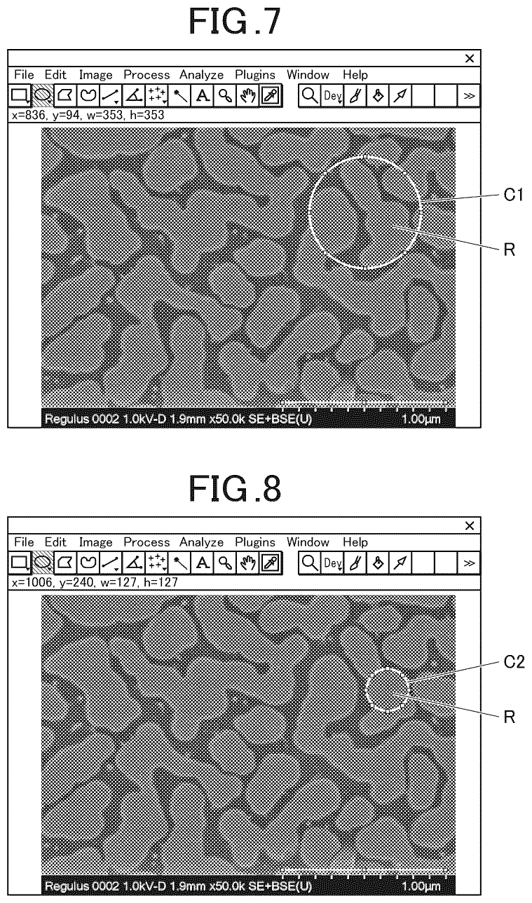

As illustrated in FIG. 7, for a given particle (e.g., particle R), the minimum circumscribed circle C1 is drawn using a circle drawing tool. In this case, w=h=353 indicated above the image is the number of pixels representing the diameter (major axis diameter) of the minimum circumscribed circle C1. That is, the physical length is 353/504=0.700 μm.
6) Measure the minor axis diameter.

As illustrated in FIG. 8, for the particle R, the maximum inscribed circle C2 is drawn using the circle drawing tool. In this case, w=h=127 indicated above the image is the number of pixels representing the diameter (minor axis diameter) of the maximum inscribed circle C2. That is, the physical length is 127/504=0.251 μm.
7) Calculate the average diameter.

The average of the measured major axis diameter and minor axis diameters is calculated.

To be specific, (0.700+0.251)/2=0.475 μm is called the diameter of the particle R illustrated in FIG. 8.

The diameters of 10 arbitrary particles are calculated in the same manner as described above, and the average of the diameters of the 10 particles is defined as the average diameter as a representative of the sample.

### <Percentage of Surface Area of Protruding Portions of Uppermost Step>

The percentage of the surface area of the protruding portions of the uppermost step relative to the surface area of the entire fine uneven structure can be calculated by a method involving capturing an image with a SEM and then subjecting the captured image to structural analysis using image processing free software. An example of the image processing free software includes “ImageJ (ImageJ 1.32S, created by Wayne Rasband)”. In addition, the percentage can be calculated by measuring image data of the fine uneven structure using an AFM and binarizing the image measured by the AFM using software manufactured by BRUKER.

In the present invention, both an image analysis method using a SEM and an image analysis method using an AFM can be used. It is sufficient that the value calculated by any of the image analysis methods falls in the range defined in the present invention.

### (SEM Image Analysis)

Hereinafter, a procedure of image analysis using an electron micrograph will be described.
1) Load into a personal computer using the free software ImageJ a SEM image of the surface of the fine uneven structure captured in advance at a magnification of 30,000 times or more using a scanning electron microscope (SEM). Since the SEM image changes with adjustment of focus, contrast, and brightness, it is preferable that the SEM image is not intentionally formed.
2) Set the definition of black and white.

In the free software ImageJ, when the Black Background is checked, a luminance value of 0 is represented by black, and a luminance value of 255 is represented by white. When the Black Background is not checked, a luminance value of 0 is represented by white, and a luminance value of 255 is represented by black. Note that the present analysis was performed with the Black Background being checked (i.e., 255 is white).
3) Remove image noise.

Smoothing processing is performed.
4) Apply a bandpass filter.

For example, a bandpass filter value of 20 to 100 is recommended. Since this setting value depends on the initial SEM image, it is preferable to appropriately set the setting value optimally.
5) Binarize the image.

8-bit is set as a setting, and a threshold value is set. In the following settings, the threshold value is set so that the Above bar (region selected in green) is at 0% by setting the bar to the right end. The threshold value is adjusted until the Below bar (region selected in blue) overlaps a black region of pores.

Since this threshold value varies depending on the contrast of the image, it is preferable that the threshold value is set by an analyst each time rather than fixed.

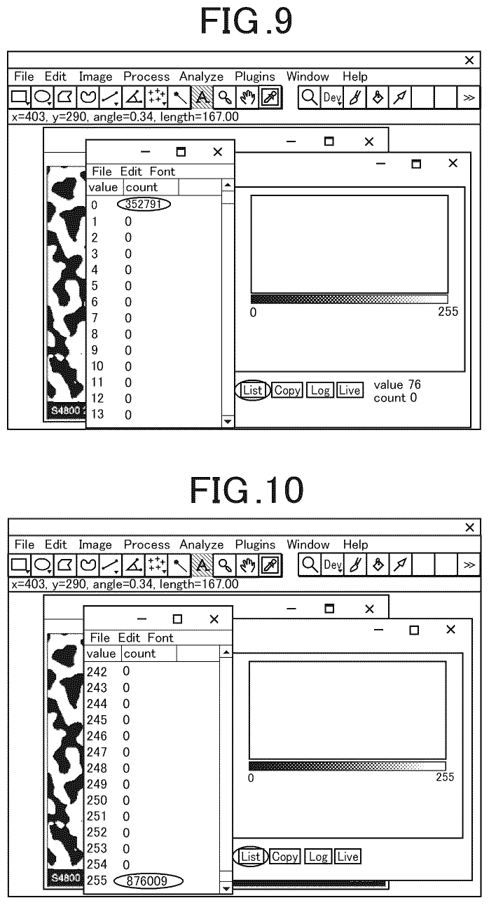

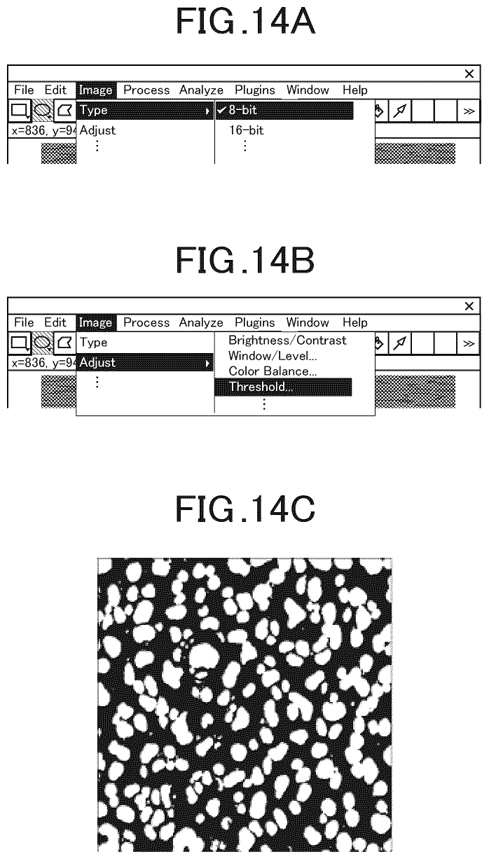

Once the threshold value is determined, the image is converted to black and white. For example, in a binarized image illustrated in FIG. 14C, white portions are the protruding portions of the uppermost step (for example, the protruding portions 22 of the second step in FIG. 5), and black portions are portions excluding the protruding portions 22 of the uppermost step (for example, the protruding portions 21 of the first step in FIG. 5).
6) Operate ImageJ to call a histogram (see FIG. 9 and FIG. 10).

When a histogram is displayed, the List button in a circle is pressed with a mouse to display histogram data as a list, as illustrated in FIG. 9. Then, the number of pixels for each tone is displayed.

In the example of FIG. 9, the number of pixels with value=0 (i.e., black pixels) is 352791.

Similarly, in the example of FIG. 10, the number of pixels with value=255 (i.e., white pixels) is 876009.
7) Determine the area ratio.

Since the protruding portions of the uppermost step are white pixels, (the number of white pixels)/(the number of white pixels+the number of black pixels)=(the area ratio of the protruding portions of the uppermost step relative to the whole).

In the examples of FIG. 9 and FIG. 10 {876009/(352791+876009)}×100=71% is the area ratio of the protruding portions of the uppermost step.

Note that when information at the time of measurement of the SEM image is included in the analysis image, it is preferable to perform image analysis through a process of, for example, excluding the information in advance so that the information does not affect the analysis.

### (AFM Image Analysis)

Next, a procedure of image analysis using an atomic force microscope (AFM) will be described.

An atomic force microscope (AFM) is a type of scanning probe microscope (SPM) that uses an atomic force between a sample and a probe to measure an uneven structure at the nanoscale.

Specifically, in the AFM, a cantilever having a sharp probe attached to the tip of a minute spring plate is brought close to the sample surface to a distance of several nanometers. Then, the unevenness of the sample is measured by an atomic force acting between the atoms at the tip of the probe and the atoms of the sample. The atomic force microscope (AFM) performs scanning while applying feedback to a piezo scanner so that the atomic force becomes constant, that is, the deflection of the cantilever becomes constant. In this method, the displacement of the Z-axis, that is, the uneven structure of the surface is measured by measuring the displacement amount fed back to the piezo scanner.

In the present invention, L-trace W manufactured by Hitachi High-Tech Corporation was used as an atomic force microscope (AFM). As the probe, SI-DF40P2, which is a silicon probe also manufactured by Hitachi High-Tech Corporation, was used.

### A) AFM Acquisition of Uneven Image of Fine Uneven Structure

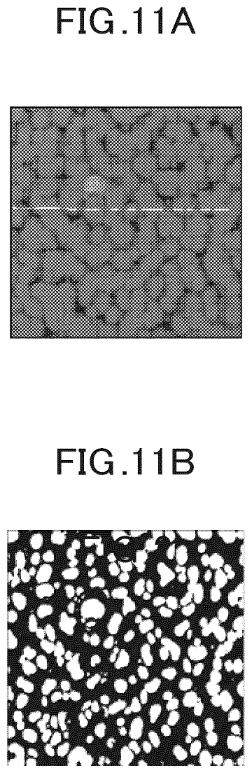

Three-dimensional uneven image data of the fine uneven structure of the functional film is measured using the above atomic force microscope (AFM) (see FIG. 11A).

### B) Binarization of AFM Data

The obtained AFM measurement image is binarized using software manufactured by BRUKER. FIG. 11B illustrates the binarized data.

The AFM data includes a collection of three-dimensional data. When this data is plotted with the vertical axis taken as the depth direction and the horizontal axis as the number of data points at each depth, the following example is obtained.

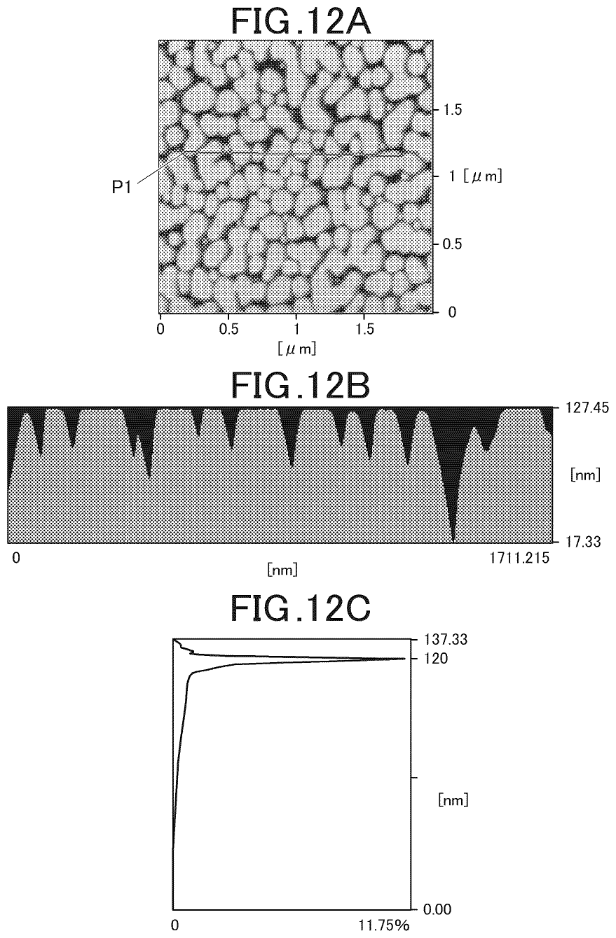

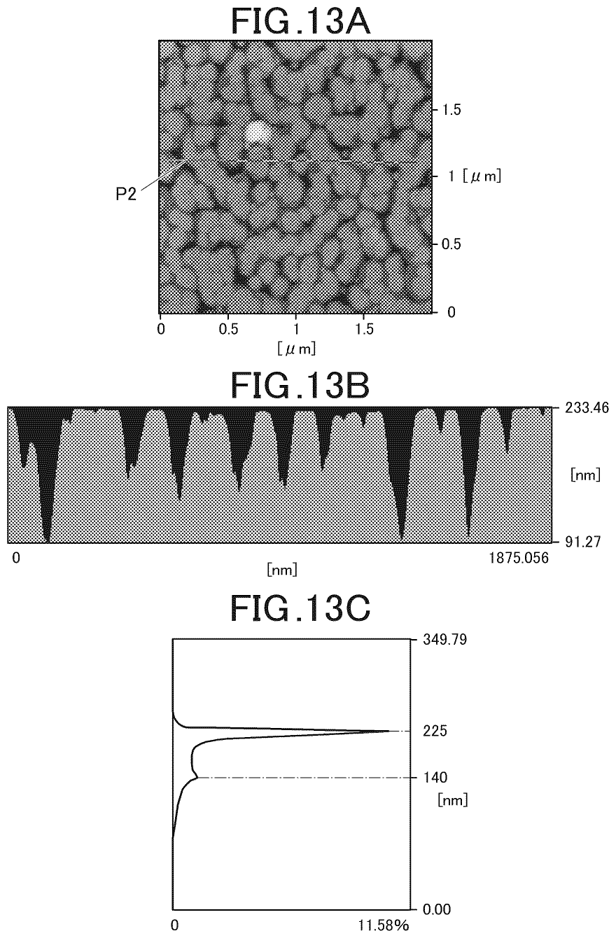

For a one-step structure, peaks of the number of data points appear at the upper surface and the lower surface as illustrated in FIG. 12C. For a two-step structure, peaks of the number of data points appear at the upper surface of the first step and the upper surface of the second step, as illustrated in FIG. 13C.

In order to obtain the occupied area of the uppermost surface of the protruding portions, binarization (color editing) is performed using the midpoint between the first peak of the number of data points at the upper surface and the second peak of the number of data points as a threshold value. The “second peak of the number of data points” means that for a one-step structure, the second peak of the number of data points is found at the lower surface, and for a two-step structure, the second peak of the number of data points is found at the upper surface of the first step.

Specifically, FIG. 12A to FIG. 12C illustrate a case of a one-step structure. FIG. 12B is a cross-sectional profile taken along a cutting line P1 shown in FIG. 12A. The horizontal axis represents the scanning position, and the vertical axis represents data in the depth direction. The vertical axis is represented by the distance from the deepest point of FIG. 12A, which is set as the zero reference point. FIG. 12C is a diagram illustrating the number of data points in the depth direction.

As illustrated in FIG. 12C, the height from the lower surface to the uppermost surface at the peak of the number of data points is 120 nm. The uppermost surface of the protruding portions of the first step (uppermost step) is located at this position. Therefore, binarization (color editing) is performed using the midpoint (60 nm) of the peak of the number of data points at the upper surface of the uppermost step (120 nm) as a threshold value. Specifically, points higher than the midpoint are displayed in white, and points lower than the midpoint are displayed in black.

FIG. 13A to FIG. 13C illustrate a case of a two-step structure. FIG. 13B is a cross-sectional profile taken along a cutting line P2 shown in FIG. 13A. The vertical axis and the horizontal axis are as described in FIG. 12B. FIG. 13C is a diagram illustrating the number of data points in the depth direction.

As illustrated in FIG. 13C, the height from the lower surface to the uppermost surface at the peak of the number of data points is 225 nm. The uppermost surface of the protruding portions of the second step (uppermost step) is located at this position. In addition, at a height of 140 nm from the lower surface, a data peak indicating the upper surface of the protruding portions of the first step is detected.

Therefore, binarization (color editing) is performed using the midpoint (182.5 nm) between the peak of the number of data points at the upper surface of the second step (225 nm) and the peak of the number of data points at the upper surface of the first step (140 nm) as a threshold value. Specifically, points higher than the midpoint are displayed in white, and points lower than the middle point are displayed in black.

Furthermore, in the present invention, the term “uppermost surface of the protruding portions of the uppermost step” refers to a surface having a height at which the number (frequency) of data points of the upper surfaces is the largest in a histogram as shown in FIG. 12. The histogram is created based on the data obtained from the AFM measurement (see FIG. 12C and FIG. 13C).

The “lowermost surface of the protruding portions of the lowermost step” refers to a surface included in the same plane as the surface having the deepest depth at which the number of data points among the lower surfaces of the recessed portions is the largest in the histogram (see FIG. 12C and FIG. 13C).

The “lower surface of a protruding portion of the uppermost step” refers to a surface included in the same plane as the lowermost surface of the recessed portions adjacent to the protruding portion of the uppermost step. That is, the “lower surface of a protruding portion of the uppermost step” refers to a surface included in the same plane as the surface having the deepest depth at which the number of data points among the lower surfaces of the adjacent recessed portions is the largest in the histogram (see 13C in FIG. 1).

Next, the image thus created is used in the same manner to measure the percentage of the surface area of the protruding portions of the uppermost step, using the free software ImageJ, which is the image analysis software described above.

A specific measurement method is described below.

Although the binarization has already been completed according to the above-described method, as a precaution, it is preferable to perform binarization processing using the image processing software as well. 8-bit is set with default settings, and the binarization is performed with Threshhold=128 as the threshold value (see FIG. 14A to FIG. 14C).

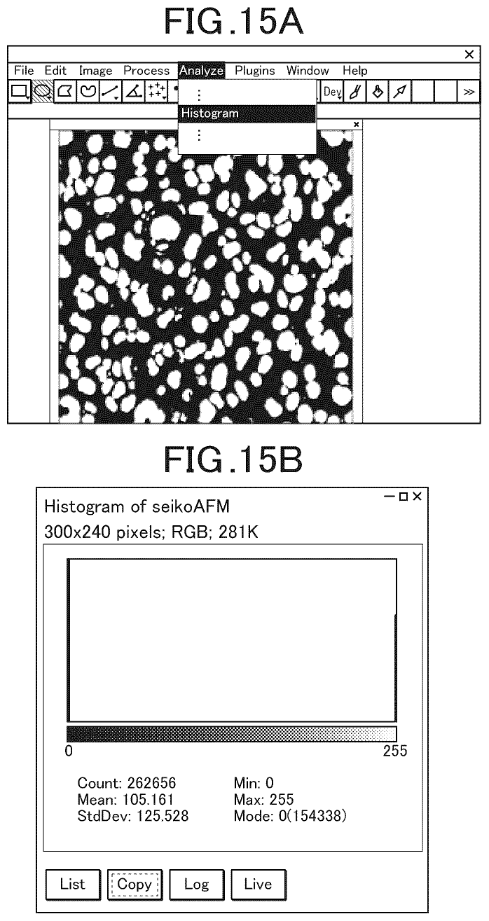

Next, a histogram of the binarized AFM image is created (see FIG. 15A and FIG. 15B).

The numbers of data points for black and white are counted to obtain the percentage of the number of data points for the uppermost surface structure (white). In the present case, the percentage of the surface area was 41%.

### <Total Average Height and Average Height of Protruding Portions of Uppermost Step>

The total average height H and the average height h of the protruding portions of the uppermost step are calculated by measuring image data of the fine uneven structure using an AFM and using software manufactured by BRUKER.

Specifically, any cross section of 1 μm or more is analyzed to calculate the distance between a surface having a height at which the number (frequency) of data points of the upper surfaces is largest and a surface having the deepest depth at which the number of data points is largest. This distance is analyzed for 10 cross sections, and the average value thereof is defined as the total average height H.

In addition, the average height h of the protruding portions of the uppermost step is obtained by the difference between the first peak of the number of data points at the upper surface and the second peak of the number of data points. Also in this case, the difference is calculated for 10 cross sections, and the average value thereof is defined as the average height h.

The “second peak of the number of data points” means that for a one-step structure, the second peak of the number of data points is found at the lower surface, and for a two-step structure, the second peak of the number of data points is found at the upper surface of the first step.

### <Reflectance Adjustment Layer>

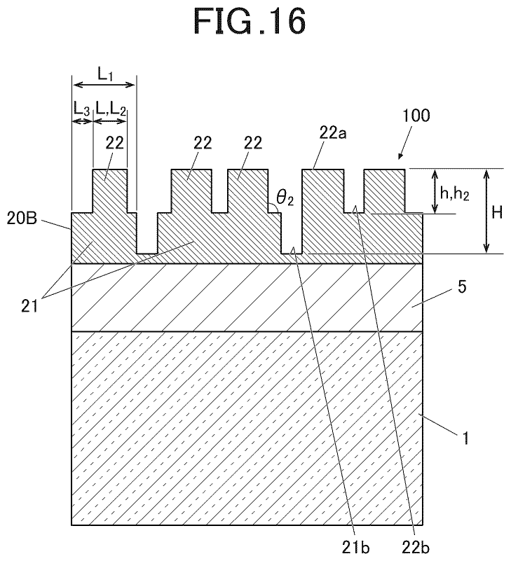

In the functional film according to the present invention, as illustrated in FIG. 16, a reflectance adjustment layer 5 made of a material different from the uneven layer 20 is preferably formed between the base material 1 and the uneven layer 20 having the fine uneven structure.

The refractive index of the functional film according to the present invention is preferably greater in the order of the uneven layer 20, the reflectance adjustment layer 5, and the base material 1.

Specifically, it is preferable that the refractive index of the uneven layer is in the range of 1.2 to 1.8, the refractive index of the reflectance adjustment layer is in the range of 1.3 to 3.5, and the refractive index of the base material is in the range of 1.45 to 5.0.

In order to set the refractive indices in these ranges, the material of each later may be controlled.

Examples of the material of the reflectance adjustment layer having a refractive index in the range of 1.3 to 3.5 include Al₂O₃, ZnS and SIC.

### <Sliding Film>

The functional film according to the present invention preferably includes a sliding film on the protruding portions. The inclusion of the sliding film is effective in preventing fogging, improves adhesiveness, achieves both the abrasion resistance and the super water repellency, and is applicable to optical device applications. As for the selection of the sliding film, when a single film having a thickness of 100 nm is formed on a white plate glass substrate manufactured by SCHOTT Corporation, and the glass substrate is left to stand at room temperature for 3 days, the film having physical property of a contact angle of 40 to 120 degrees is preferable. In particular, a sliding film having a contact angle that differs by 20 degrees or more from the contact angle of the main component of the fine structure is more preferable.

Examples of the sliding film include Ta₂O₅—TiO₂ (trade name: OA-600, manufactured by Canon Optron, Inc.), Ta₂O₅, TiO₂, SiC, Al₂O₃, and HfO₂.

Examples of a method for forming the sliding film include an ion-assisted deposition method (IAD method), a sputtering method, and a CVD method, in addition to the usual vacuum deposition method. The thickness of the sliding film is preferably in the range of 0.1 to 20 nm.

### <Water-Repellent Film>

The functional film according to the present invention preferably has on its uppermost surface, a water-repellent film that contains a water-repellent material and has a contact angle of 110 degrees or more with respect to water under conditions of 23° C. and 50% RH.

That is, it is preferable to provide the protruding portions with a film containing a water-repellent material (hereinafter, also referred to as a “water-repellent film”) from the viewpoint of improving water repellency.

The contact angle is measured as follows. For example, 10 μL of pure water is dropped on a water-repellent film under an environment of 23° C. and 50% RH by using a contact angle measuring apparatus G-1 manufactured by Erma Inc. Then, a static contact angle after 5 seconds of dropping is measured. This angle is defined as the contact angle.

Examples of the water-repellent material include fluorine-based and silicon-based water-repellent materials. Specific examples thereof include FLUOROSURF (manufactured by Fluoro Technology Co., Ltd.), OPTOOL UD120 (manufactured by Daikin Industries, Ltd.), and SC100 (manufactured by Canon Optron, Inc.).

Examples of a method for forming the water-repellent film include a spin coating method, a dip coating method, and a vacuum deposition method.

### [Method for Producing Functional Film]

The method for producing a functional film of the present invention is a method for producing a functional film having an uneven structure and uses the above-described apparatus for producing a functional film of the present invention.

Hereinafter, an example of the method for producing a functional film will be described, but the present invention is not limited thereto. The method is not particularly limited as long as the method includes a process of etching using the above-described production apparatus of the present invention.

The method for producing a functional film of the present invention preferably has a process of forming a reflectance adjustment layer between a base material and the uneven layer having the fine uneven structure. The reflectance adjustment layer is made of a material different from that of the uneven layer.

Furthermore, the method for producing a functional film of the present invention preferably includes, after formation of an inorganic layer and before formation of a mask, a process of disposing (providing), on the inorganic layer, a compound that reacts with a metal that is the main component of the mask. Hereinafter, this process is also referred to as a self-assembly promoting compound disposition process. This causes the compound that reacts with the metal to chemically react with the metal in the mask formed in a later process. As a result, the metal in the mask migrates, and the mask is formed in a mesh shape by self-assembly without heating or the like. Therefore, resin or the like that cannot be heated to a high temperature can be used as the material of the base material, leading to cost reduction. In addition, since heating is not required, time is shortened, leading to cost reduction and energy saving.

In the self-assembly promoting compound disposition process, not before the mask is formed but after the mask is formed, the compound that reacts with the metal may be disposed on the mask. Also in this case, the compound that reacts with the metal reacts with the metal in the mask, and the metal in the mask migrates, whereby the mask is formed in a mesh shape. As a result, the same effect can be obtained as in the case where the self-assembly promoting compound disposition process is performed before the mask formation.

Hereinafter, a reflectance adjustment layer formation process, an inorganic layer formation process, a self-assembly promoting compound disposition process, a mask formation process, and an etching process will be described. In the following description, a case where the self-assembly promoting compound disposition process is performed before the mask formation process is described as an example, but the present invention is not limited thereto.

FIG. 17A to FIG. 17G are process diagrams illustrating an example of the method for producing a functional film. In the following description, the method for producing a functional film having a fine uneven structure that includes protruding portions having a two-step shape will be described, but the present invention is not limited to the production method described below.

### (1) Reflectance Adjustment Layer Formation Process

As illustrated in FIG. 17A, the reflectance adjustment layer 5 is formed on the base material 1 by, for example, a dry film formation method.

Examples of the dry film formation method include vacuum deposition, ion beam deposition, ion plating, and sputtering methods such as sputtering, ion beam sputtering, and magnetron sputtering. Particularly, in the present invention, ion-assisted deposition (IAD) or sputtering is preferable.

As the material of the reflectance adjustment layer, a material different from that of the uneven layer (inorganic layer) is used. In particular, the material is preferably selected so that the refractive index is greater in the order of the uneven layer, the reflectance adjustment layer, and the base material.

The thickness of the reflectance adjustment layer is preferably in the range of 1 to 200 nm.

### (Base Material)

The base material (substrate) is not particularly limited, and for example, is preferably made of an inorganic material, an organic material, or a combination of the two.

Examples of the inorganic material include glass, fused quartz glass, synthetic quartz glass, silicon, and chalcogenide. Examples of the organic material include polyethylene terephthalate (PET), acrylic resin, vinyl chloride resin, cycloolefin polymer (COP), cycloolefin copolymer (COC), polymethyl methacrylate resin (PMMA), polycarbonate resin (PC), polypropylene (PP), and polyethylene (PE). Examples of an ultraviolet curable resin include: radical polymerization type acrylate resin, urethane acrylate, polyester acrylate, polybutadiene acrylate, epoxy acrylate, silicon acrylate, amino resin acrylate, and ene-thiol resin; and cationic polymerization type vinyl ether resin, alicyclic epoxy resin, glycidyl ether epoxy resin, urethane vinyl ether, and polyester vinyl ether. Examples of a thermosetting resin include epoxy resin, phenol resin, unsaturated polyester resin, urea resin, melamine resin, silicon resin, and polyurethane. The base material may be an inorganic material such as glass on which a film made of an organic material is formed.

In the present invention, when the functional film of the present invention is used in an optical device as described below, it is preferable to use glass or resin as the base material from the viewpoint of transparency. When the functional film of the present invention is used in an inkjet head, it is preferable to use silicon as the base material. For an infrared lens, it is preferable to use silicon, germanium, or chalcogenide as the base material. Furthermore, when the functional film is used in a mold, it is preferable to use SiC, cemented carbide, or the like as the base material.

### (2) Inorganic Layer Formation Process

As illustrated in FIG. 17A, the inorganic layer 2 containing an inorganic substance as its main component is formed on the reflectance adjustment layer 5 by, for example, a dry film formation method. Note that when the reflectance adjustment layer 5 is not provided, although not illustrated, the inorganic layer 2 is formed on the base material 1.

Examples of the dry film formation method include vacuum deposition, ion beam deposition, ion plating, and sputtering methods such as sputtering, ion beam sputtering, and magnetron sputtering. Particularly, in the present invention, ion-assisted deposition (IAD) or sputtering is preferable.

The thickness of the inorganic layer varies depending on the type of the inorganic substance. When the inorganic substance is SiO₂, the thickness is preferably in the range of 100 to 400 nm. When the inorganic substance is SiC, the thickness is preferably in the range of 100 to 1000 nm. When the inorganic substance is SiOC, the thickness is preferably in the range of 100 to 500 nm. When the inorganic substance is SiCN, the thickness is preferably in the range of 100 to 500 nm.

### (3) Self-Assembly Promoting Compound Disposition Process

Next, as illustrated in FIG. 17B, after the inorganic layer formation process and before the mask formation process, a compound (also referred to as a “self-assembly promoting compound”) 6 that reacts with a metal that is the main component of the mask is preferably disposed (provided) on the inorganic layer 2.

Note that although the self-assembly promoting compound 6 is illustrated in the form of a continuous layer (film) in FIG. 17B, the compound 6 may be simply dotted in the form of particles or formed in the form of an intermittent layer.

By disposing the self-assembly promoting compound and covering, in the subsequent mask formation process, the self-assembly promoting compound with a mask, the mask containing the compound is recognized as a mesh-like mask.

This is due to the chemical reaction between the self-assembly promoting compound and the metal in the mask, which causes the metal to migrate and forms the mask into a mesh shape. In this way, the mask is formed in a mesh shape without heating the mask at a high temperature. Therefore, the compound that reacts with the metal is also referred to as the self-assembly promoting compound.

The self-assembly promoting compound is a compound that reacts with a metal that is the main component of the mask.

The self-assembly promoting compound is a compound that easily causes the metal to migrate and preferably contains, for example, Na (sodium), I₂ (iodine), Cl₂ (chlorine), or the like.

In particular, the self-assembly promoting compound preferably has hygroscopicity. As a result, after the self-assembly promoting compound is formed using a dry film formation method, by exposing the self-assembly promoting compound to an atmospheric environment containing moisture, particles in the compound can be separated from each other to form a layer having a mesh shape or isolated particles (dots).

Such a self-assembly promoting compound preferably has a solubility of 0.5 g/100 mL or more in water at 20° C. By setting the solubility in the above range, the mask can be formed in a mesh shape.

Examples of the compound having a solubility of 0.5 g/100 mL or more include a LiCl (solubility: 76.9 g/100 mL (20° C.)), NaCl (solubility: 35.9 g/100 mL (20° C.)), MgCl₂·6H₂O (solubility: 54.3 g/100 mL (20° C.)), KCl (solubility: 34.0 g/100 mL (20° C.)), CaCl₂ (solubility: 74.5 g/100 mL (20° C.)), Na₂CO₃ (solubility: 22 g/100 mL (20° C.)), NaF (solubility: 4.06 g/100 mL (20° C.)), and KI (solubility: 148 g/100 mL (20° C.)).

The self-assembly promoting compound is preferably an inorganic salt. It is preferable that at least a portion of the inorganic salt contains an alkali metal from the viewpoint that the high-temperature and high-humidity resistance of hydrophilicity is improved.

NaCl, NaF, MgCl₂·6H₂O, and the like are preferable as inorganic salts that satisfy the above range of solubility and are alkali metals. In particular, the self-assembly promoting compound preferably contains Na.

The average particle size of particles constituting the self-assembly promoting compound is preferably in the range of 10 to 1000 nm. The average particle size of the particles can be measured by an electron microscope (S-4800, manufactured by Hitachi High-Tech Corp.).

The self-assembly promoting compound is applied onto the inorganic layer by, for example, a dry film formation method.

Examples of the dry film formation method include deposition methods such as vacuum deposition, ion beam deposition, ion plating, and ion-assisted deposition (hereinafter, also referred to as “IAD” in the present invention), and sputtering methods such as sputtering, ion beam sputtering, and magnetron sputtering. Among these, the vacuum deposition, IAD, or sputtering is preferable. In particular, a resistance heating vacuum deposition method is preferable.

The thickness of the layer made of the self-assembly promoting compound thus formed is preferably in the range of 0.1 to 100 nm.

In the above description, the self-assembly promoting compound is disposed before the mask formation process, but the present invention is not limited thereto. For example, after the mask formation process described below, the self-assembly promoting compound may be disposed on the mask.

### (4) Mask Formation Process

Next, as illustrated in FIG. 17B, a mask 3 is formed on the self-assembly promoting compound 6. Furthermore, the mask formation process is performed once.

The mask contains a metal as its main component. In addition, for example, a metal mask including a metal portion and an exposed portion is preferable.

Examples of the metal that is the main component of the mask include silver (Ag), indium, and tin. Silver is particularly preferable.

The layer thickness of the mask is preferably in the range of 2 to 100 nm.

Although it also depends on the film formation conditions, for example, when a metal mask is formed to have a layer thickness of 2 nm at a base material temperature of 370° C. and a rate of 3 Å by using a deposition method, the metal mask becomes particle-like. In addition, for example, when a metal mask is formed to have a layer thickness of 12 to 15 nm at a base material temperature of 170° C. and a rate of 3 Å by using a deposition method, the metal mask tends to become mesh-like. Furthermore, for example, when a metal mask is formed to have a layer thickness of 10 nm at a base material temperature of 30° C. and a rate of 3 Å by using a sputtering method, the metal mask tends to become porous.

As described above, the average diameter, the percentage of the surface area, and the average height of the protruding portions formed by etching are controlled by the film formation conditions of the metal mask, the base material temperature, the film formation rate, and the film formation thickness.

In addition, it is preferable that the film formation temperature of the metal mask is in the range of 20 to 400° C.

The average diameter L, the percentage of the surface area, and the average height h of the protruding portions formed by etching are also controlled by the film formation temperature of the metal mask.

Here, as described above; by providing the self-assembly promoting compound adjacent to the upper surface or the lower surface of the mask in advance, the self-assembly promoting compound absorbs moisture through exposure to the atmosphere or the like. As a result, the self-assembly promoting compound chemically reacts with the metal in the mask. Thus, the metal in the mask migrates, and the mask is formed in a mesh shape by self-assembly without heating or the like. (see FIG. 17C). As in the past, when the self-assembly promoting compound is not applied, the metal mask is formed in a mesh shape by high-temperature heating. However, when the self-assembly promoting compound is applied, the high-temperature heating becomes unnecessary. Therefore, resin or the like that cannot be heated to a high temperature can be used as the material of the base material, leading to cost reduction. Furthermore, since heating is not required, time is shortened, leading to energy saving.

### (5) Etching Process

Next, the inorganic layer 2 is etched. The above-described apparatus for producing a functional film of the present invention is used for the etching.

Further, the etching process is preferably performed at least once.

In the present invention, the “number of etching processes” is counted as one when an object to be etched is placed in an etching apparatus, etching is started, and the object is exposed to the atmosphere. Therefore, even when etching conditions are changed during etching, the etching is counted as one etching unless the object to be etched is exposed to the atmosphere.

In the etching process, etching is preferably performed under a combination of anisotropic etching conditions and isotropic etching conditions.

Specifically, first, etching is performed under anisotropic etching conditions, and then etching is performed under isotropic etching conditions. It is preferable to repeat this combination of anisotropic etching and isotropic etching a plurality of times.

For example, it is preferable that after anisotropic etching, isotropic etching is performed, and then anisotropic etching is performed again. More preferably, a series of processes including anisotropic etching, isotropic etching, and anisotropic etching are performed without exposure to the atmosphere. In this case, the etching is considered to be performed once.

Alternatively, after anisotropic etching is performed, the mask may be exposed to the atmosphere and stored under humidity for one hour to promote the migration of the mask, and then anisotropic etching may be performed again. In this case, the etching is considered to be performed twice.

In particular, when the number of steps of the protruding portions (integer Y) is two or more, that is, when the uneven structure has a two- or more-step shape, anisotropic etching and isotropic etching are performed in combination. When the number of steps of the protruding portions (integer Y) is 1, that is, when the uneven structure has a one-step shape, the uneven structure can be formed only by anisotropic etching.

Here, the “isotropic etching” refers to etching that proceeds at a uniform rate in all directions of the object. Further, the “anisotropic etching” refers to etching that proceeds faster in a specific direction of the target. That is, in the anisotropic etching, etching preferentially proceeds only in a specific direction of the object.

Therefore, etching preferentially proceeds in the depth direction of the inorganic layer by performing anisotropic etching using an etching apparatus (the apparatus for producing a functional film of the present invention) from the side facing the upper surface through the mask formed as described above. This forms unevenness in the inorganic layer.

Further, by performing isotropic etching, the etching proceeds in both the depth and lateral directions of the mask formed as described above in the same manner. This allows the size of the mask to be changed.

### (5-1) Anisotropic Etching

In the anisotropic etching, the inorganic layer is etched from the side facing the upper surface through the mask formed as described above using an etching apparatus (the apparatus for producing a functional film of the present invention). Recessed portions are formed by the anisotropic etching, and as a result, protruding portions are formed.

The anisotropic etching preferably includes first anisotropic etching and second anisotropic etching.

That is, it is preferable that after the first anisotropic etching is performed (see FIG. 17D), isotropic etching described below is performed (see FIG. 17E), and then the second anisotropic etching is performed (see FIG. 17F). In addition, it is preferable not to perform exposure to the atmosphere during the first anisotropic etching, the isotropic etching, and the second anisotropic etching from the viewpoint that costs can be reduced.

The first anisotropic etching is preferably performed to such an extent that the surface of the reflectance adjustment layer is not exposed. Specifically, the etching time is controlled such that the total average height H described above is 1 μm or less. In this way, the recessed portions (protruding portions 21) of the first step are formed by the first anisotropic etching.

The second anisotropic etching is performed after the isotropic etching described below is performed. Since the size of the mask is reduced by the isotropic etching, in the second anisotropic etching, the inorganic layer is etched from the side facing the surface through the reduced mask using the etching apparatus. It is preferable to perform etching by the second anisotropic etching to such an extent that the reflectance adjustment layer is not exposed from the recessed portions of the first step. To be specific, the etching time is controlled so that the depth of the recessed portions of the second step becomes 10 nm to 200 nm. This forms the recessed portions (protruding portions 22) of the second step.

The first anisotropic etching is preferably performed in the range of 0.1 KHZ to 1 MHZ, and the second anisotropic etching is preferably performed in the range of 0.1 KHZ to 1 MHZ.

The power density of the first anisotropic etching is preferably in the range of 0.01 to 1 W/cm² from the viewpoint that the selectivity of the metal mask is increased. The power density of the second anisotropic etching is preferably in the range of 0.01 to 1 W/cm².

The time of the first anisotropic etching is preferably in the range of 1 minute to 2 hours, and the time of the second anisotropic etching is preferably in the range of 1 minute to 2 hours.

In addition, as for conditions inside the chamber of the etching apparatus, it is preferable that the temperature is in the range of 5 to 30° C. and the initial degree of vacuum is in the range of 1 to 20 Pa.

For the first and second anisotropic etching, reactive dry etching using an etching apparatus (the apparatus for producing a functional film of the present invention) is performed.

As an etching gas, for example, CHF₃, CF₄, COF₂, SF₆, or the like is used. As a result, etching is performed in a predetermined size from the inorganic layer to the vicinity of the upper surface of the reflectance adjustment layer, and a plurality of recessed portions are formed, whereby protruding portions are formed. That is, the constituent layer corresponding to the exposed portion of the metal mask is etched.

The flow rate of the etching gas used in the first anisotropic etching is preferably in the range of 5 to 100 sccm. The flow rate of the etching gas used in the second anisotropic etching is preferably in the range of 10 to 30 sccm.

### (5-2) Isotropic Etching

In the isotropic etching, the mask formed as described above is etched using the apparatus for producing a functional film of the present invention as an etching apparatus. By the isotropy etching, the mask is etched in the depth and lateral directions, and the size of the mask is changed (see FIG. 17E).

The isotropic etching is preferably performed by changing the degree of vacuum or the power density at least once during the etching.

For example, initially, the isotropy etching is performed with the degree of vacuum in the range of 5 to 20 Pa and the power density in the range of 0.01 to 0.5 W/cm². Then, it is preferable to change the degree of vacuum to a range of 1 to 10 Pa and the power density to a range of 0.03 to 1.0 W/cm² during the process.

In addition, the time of the initial isotropic etching is preferably in the range of 1 minute to 2 hours, and the time of the isotropic etching after the condition change is preferably in the range of 1 minute to 1 hour.

Furthermore, as for the conditions inside the chamber of the etching apparatus, it is preferable that the temperature is in the range of 5 to 30° C. and the initial degree of vacuum is in the range of 1 to 20 Pa.

For the isotropic etching, reactive dry etching using the etching apparatus is performed. As an etching gas, for example, Ar, O₂, N₂, CHF₃, CF₄, COF₂, SF₆, or the like is used. Thus, the mask is isotropically etched, and the size of the mask is changed.

The flow rate of the etching gas used in the isotropy etching is preferably in the range of 5 to 100 sccm.

It is preferable that the mask has an average diameter in the range of 10 to 200 nm when viewed from above and an average height in the range of 5 to 50 nm.

### (6) Mask Peeling Process

In a mask peeling process, as illustrated in FIG. 17G, the mask formed on the surface is removed.

Specifically, the metal mask is removed by wet etching using a chemical agent such as nitric acid, acetic acid, iodine, or potassium iodide. Alternatively, the metal mask may be removed by dry etching using, for example, Ar (argon) or O₂ (oxygen) as an etching gas.

By removing the mask, the fine uneven structure including the protruding portions of the first and second steps is formed.

As described above, according to the method for producing a functional film of the present invention, the protruding portions of the first and second steps can be formed by a single mask formation process, thereby reducing costs.

### (7) Formation Process of Sliding Film and Water-Repellent Film

In a process of forming the sliding film and the water-repellent film, it is preferable to form the sliding film on the protruding portions of a two-step shape (the protruding portions 21 of the first step and the protruding portions 22 of the second step) using, for example, a dry film forming apparatus.

Finally, the water-repellent film is preferably formed on the sliding film using a dry film forming apparatus or a wet film forming apparatus. Note that the illustration of the sliding film and the water-repellent film is omitted.

Through the above processes, the functional film 100 of the present invention can be obtained.

In the above production method, a method for producing a functional film having the fine uneven structure 20B including protruding portions of a two-step shape has been described. However, depending on the Mohs hardness of the inorganic substance, the functional film may have a fine uneven structure including protruding portions of a one-step shape. Furthermore, the functional film may have a fine uneven structure including protruding portions of a three- or more-step shape.

When a functional film having a fine uneven structure including protruding portions of a three-step shape is produced, it is preferable that the thickness of the metal mask at the time of forming the protruding portions of the first step is in the range of 5 to 100 nm. In addition, it is preferable that the thickness of the metal mask at the time of forming the protruding portions of the second step is in the range of 5 to 70 nm. Furthermore, it is preferable that the thickness of the metal mask at the time of forming the protruding portions of the third step is in the range of 2 to 10 nm.

It is preferable that the film formation temperature of the metal mask at the time of forming the protruding portions of the first step is in the range of 150 to 400° C. In addition, it is preferable that the film formation temperature of the metal mask at the time of forming the protruding portions of the second step is in the range of 100 to 400° C. Furthermore, it is preferable that the film formation temperature of the metal mask at the time of forming the protruding portions of the third step is in the range of 100 to 400° C.

### [Field of Application of Functional Film]

### <Optical Device>

The functional film produced by the production apparatus of the present invention is a functional film having both the abrasion resistance and the super water repellency. In the present invention, it is preferable that an optical device includes the functional film.

Furthermore, it is preferable that the optical device is a lens, a cover glass of a lens, an antibacterial cover member, an antifungal coating member, or a mirror. As such an optical device, for example, an in-vehicle lens, a communication lens, an optical member such as an infrared sensor and a LiDAR window, an optical window or a lens of a monitoring camera, an optical window or a lens of a drone, an antibacterial lens for an endoscope, a member or an antibacterial cover member of a PC, a member or an antibacterial cover member of a smartphone, glasses, ceramics such as a toilet and tableware, an antifungal coating of a bath, an antifungal coating of a sink, or a building material (window glass) is suitably used. In particular, the functional film according to the present invention is suitable for an in-vehicle lens.

Furthermore, in the optical device to which the functional film is applied, the base material is preferably glass or resin from the viewpoint of transparency. The inorganic substance as the main component contained in the functional film is preferably a Si-containing material such as SiO₂, Si, or SiC from the viewpoint that a reaction product is easily formed by a fluorine gas and etching is easily performed.

### <Inkjet Head>

The functional film can also be applied to an inkjet head.

In addition, the base material of the inkjet head to which the functional film is applied is preferably silicon from the viewpoint of durability and processing characteristics. Further, the inorganic substance as the main component contained in the functional film is preferably SiC from the viewpoint of ink wiping properties.

### <Mold>

The functional film can also be applied to a mold.

The base material of the mold to which the functional film is applied is preferably SiC or a cemented carbide from the viewpoint of strength. The inorganic substance as the main component contained in the functional film is preferably SiC, which is a Si-containing material, from the viewpoint that a reaction product is easily formed by a fluorine gas, etching is easily performed, and the material is hard.

### Examples

Hereinafter, the present invention will be specifically described with reference to examples, but the present invention is not limited thereto. Note that the operations in the following examples were performed at room temperature (25° C.) unless otherwise specified. Further, unless otherwise specified, “%” and “parts” mean “% by mass” and “parts by mass”, respectively.

### [Production of Functional Film 1]

### <Preparation of Base Material>

As a base material, a glass substrate, TAFD5G (manufactured by HOYA Corporation) (refractive index: 1.84), was prepared.

### <Formation of Inorganic Layer 1>

The glass substrate was placed in an IAD vacuum deposition apparatus. SiO₂ was loaded as a film-forming material and deposited at a film-forming rate of 1 Å/sec to form an inorganic layer (SiO₂ layer) having a layer thickness of 293 nm.

IAD conditions were as follows: acceleration voltage of 1000 V, acceleration current of 1000 mA, suppressor voltage of 500 V, neutralization current of 1500 mA, and neutral gas Ar with 10 sccm.

### (In-Chamber Conditions)

Heating temperature: 370° C.
Initial degree of vacuum: 3.0×10⁻³ Pa

### (Evaporation Source of Film-Forming Material)

Electron gun

### (IAD Ion Source)

RF ion source NIS-175-3 manufactured by SHINCRON CO., LTD.
Film-forming material of inorganic layer: SiO₂ (trade name: SiO₂, manufactured by Canon Optron, Inc.)

### <Film Formation of Ag Mask>

An Ag (silver) mask was formed on the formed inorganic layer. The Ag mask was formed using a film formation apparatus (BMC-800T, manufactured by SHINCRON CO., LTD.) under the following conditions. The thickness of the Ag mask was 25 nm.
Heating temperature: 210° C.
Initial degree of vacuum: 1.33×10⁻³ Pa
Film formation rate: 3 Å/sec

### <Etching>

Samples on which the Ag mask was formed were etched using an etching apparatus.

The etching apparatus used is as follows.

The number of plasma electrodes was eight in total, and four pairs of plasma electrodes, each including an RF electrode and a ground electrode, were disposed in the chamber. Specifically, although not illustrated, a first ground electrode, a first RF electrode, a second ground electrode, a second RF electrode, a third ground electrode, a third RF electrode, a fourth ground electrode, and a fourth RF electrode were disposed in this order from top to bottom in the chamber, facing each other.

Furthermore, the electrodes were connected in parallel. That is, the first to fourth RF electrodes were disposed so as to be electrically parallel to each other, and the first to fourth ground electrodes were disposed so as to be electrically parallel to each other.

The total area of these plasma electrodes was 14400 cm².

Water was used as an internal cooling solvent that was allowed to flow through each electrode. The temperature of the cooling water was 20° C.

The position of the exhaust port for the etching gas was set to a position facing the introduction port (that is, a position at 180 degrees from each other when the chamber is viewed in plan view).

In the etching apparatus as described above, the samples were placed on the four pairs of plasma electrodes. Specifically, the samples were placed on the first to fourth RF electrodes.

The etching conditions were as follows: input power of 300 W, gas flow rate of 20 sccm, and degree of vacuum of 10 pa. Further, a power with a frequency of 1 KHZ was independently applied to the plasma electrodes.

### (In-Chamber Conditions)

Device: BIG CUBE manufactured by You Patenter Co., Ltd.
Temperature: 20° C.
Initial degree of vacuum: 10.0 Pa

### (Etching Gas)

CHF₃

### (Etching Gas Flow Rate)

20 sccm

### (Power Density)

0.035 W/cm²

Etching was performed at an etching rate of 2 nm/minute to form an uneven shape.

### <Peeling of Ag Mask>

After the etching process, the samples were immersed in Pure Etch AU 100 (Hayashi Pure Chemical Ind., Ltd.) for 5 seconds to remove the Ag. Thereafter, the samples were washed with pure water, and cleaning was performed using a UV ozone device (Technovision, Inc.) for 600 seconds.

In this manner, a functional film 1 was obtained.

### [Production of Functional Films 2 and 3]

Functional films 2 and 3 were obtained in the same manner as in the production of the functional film 1 except that the total area of the plasma electrodes and the number of electrodes were changed as shown in the following table.

### [Production of Functional Film 4]

A functional film 4 was obtained in the same manner as in the production of the functional film 1 except that the total area of the plasma electrodes, the number of electrodes, and the connection method were changed as shown in the following table.

Here, the connection method of series means that the first ground electrode and the second ground electrode are disposed so as to be electrically in series and the first RF electrode and the second RF electrode are disposed so as to be electrically in series.

### [Production of Functional Film 5]

A functional film 5 was produced in the same manner as in the production of the functional film 2 except that when the chamber was viewed in plan view, the exhaust port was disposed such that the exhaust port and the introduction port for the etching gas were positioned 60 degrees apart from each other, with the central portion (the plasma electrodes) of the chamber at the center.

### [Production of Functional Film 6]

A functional film 6 was produced in the same manner as in the production of the functional film 2 except that the cooling water was not allowed to flow through the inside of the plasma electrode.

### [Production of Functional Film 7]

A functional film 7 was produced in the same manner as in the production of the functional film 2 except that the frequency applied to the plasma electrode was changed as shown in the following table.

### [Production of Functional Film 8]

A functional film 8 was produced in the same manner as in the production of the functional film 1 except that the total area of the plasma electrodes, the number of electrodes, the position of the exhaust port for the etching gas, and the frequency were changed as shown in the following table, and the cooling water was not allowed to flow through the inside of the plasma electrodes.

### [Evaluation]

### <Processing Time>

In order to compare how many samples can be processed per hour, the time for which etching was performed is shown in the following table.

### <Number of Placeable Samples>

The number of samples that could be placed in the etching apparatus used in the production of each functional film was calculated.

The number of samples that can be placed is the number of samples when the samples are disposed on the electrode(s) so that “Area occupied by samples placed on electrode(s)” is calculated by the following formula.

(Area occupied by samples placed on electrode(s))=(Area of electrode(s) to be disposed)×50% Formula (A):

Note that a portion of the electrode(s) on which no sample is placed is a gap between the samples.

### <Total Number of Processed Samples per Hour>

The total number of processed samples per hour is calculated by the following Formula (B) and Formula (C).

Number of times of processing per hour=60 minutes+processing time (minute) Formula (B):

Total number of processed samples per hour=Number of times of processing per hour×Number of placeable samples Formula (C):

In Formula (B), the “processing time (minute)” is as described above.

In Formula (C), the “number of placeable samples” is the value calculated above.

### <Degree of Damage to Mask>

The degree of damage to the mask was evaluated by the thickness of the remaining Ag mask after the Ag mask having a thickness of 25 nm was formed as described above and etched. The evaluation criteria are as follows. In the evaluation criteria, AAA, AA, and A have no practical problem.

### (Criteria)

AAA: Remaining Ag mask thickness is 10 nm or more
AA: Remaining Ag mask thickness is 5 nm or more and less than 10 nm
A: Remaining Ag mask thickness is 3 nm or more and less than 5 nm
B: Remaining Ag mask thickness is less than 3 nm

### <Etching Uniformity>

The uniformity of etching was evaluated based on numerical values calculated from the in-plane distribution characteristics of the etching amount in the plasma electrodes.

The in-plane distribution of the etching amount in the plasma electrodes can be measured by the following method.

When the number of plasma electrodes is two pairs, samples are placed on the four corners and the center of each of the first-stage RF electrode and the second-stage RF electrode. That is, a total of 10 samples (5 samples×2 stages) are placed. Then, the reflectance of each sample is measured after the etching. The average reflectance is calculated from the measured reflectance. Then, the standard deviation a is calculated, and the standard deviation a is defined as a variation value.

The reflectance was measured using a micro-region spectral reflectance measuring apparatus (USPM-RU, manufactured by Olympus Corporation).

From the calculated variation value, evaluation was performed according to the following criteria. In the evaluation criteria, AAA, AA, and A have no practical problem.

When the number of plasma electrodes is four pairs, samples are placed on the four corners and the center of each of the first- to fourth-stage RF electrodes. That is, a total of 20 samples (5 samples×4 stages) are placed, each reflectance is measured, and the variation value of the average reflectance is calculated.

When the number of plasma electrodes is one pair, samples are placed on the four corners and the center of the RF electrode. That is, a total of 5 samples (5 samples×1 stage) are placed, each reflectance is measured, and the variation value of the average reflectance is calculated.

### (Criteria)

AAA: Variation value is less than 1%
AA: Variation value is 1% or more and less than 3%
A: Variation value of 3% or more and less than 5%
B: Variation value is 5% or more

TABLE II

| | | | | | | | | | POSITION |
|---|---|---|---|---|---|---|---|---|---|
| | TOTAL AREA | | | | | ELECTRODE | | | OF |
| | OF PLASMA | HIGH- | | NUMBER OF | | TEMPER- | WATER- | | EXHAUST |
| FUNCTIONAL | ELECTRODES | FREQUENCY | | ELECTRODES | CONNECTION | ATURE | COOLING | ETCHING | PORT |
| FILM No. | [cm²] | FREQUENCY | | [PAIRS] | METHOD | [° C.] | MECHANISM | GAS | [DEGREES] |
| 1 | 14400 | 1 | KHz | 4 | PARALLEL | 20 | PRESENT | CHF₃ | 180 |
| 2 | 7200 | 1 | KHz | 2 | PARALLEL | 20 | PRESENT | CHF₃ | 180 |
| 3 | 3600 | 1 | KHz | 1 | — | 20 | PRESENT | CHF₃ | 180 |
| 4 | 7200 | 1 | KHz | 2 | SERIES | 20 | PRESENT | CHF₃ | 180 |
| 5 | 7200 | 1 | KHz | 2 | PARALLEL | 20 | PRESENT | CHF₃ | 60 |
| 6 | 7200 | 1 | KHz | 2 | PARALLEL | 80 | ABSENT | CHF₃ | 180 |
| 7 | 7200 | 100 | KHz | 2 | PARALLEL | 20 | PRESENT | CHF₃ | 180 |
| 8 | 314 | 13.56 | MHz | 1 | — | 80 | ABSENT | CHF₃ | 120 |

TABLE III

| | EVALUATION RESULTS | | | | | |
|---|---|---|---|---|---|---|
| | | | TOTAL | | | |
| | | NUMBER OF | NUMBER OF | DEGREE | | |
| | | PLACEABLE | PROCESSED | OF | | |
| FUNCTIONAL | PROCESSING | SAMPLES | SAMPLES PER | DAMAGE | ETCHING | |
| FILM No. | TIME [MIN] | [PCS] | HOUR [PCS] | TO MASK | UNIFORMITY | REMARKS |
| 1 | 60 | 9172 | 9172 | AAA | AAA | PRESENT |
| | | | | | | INVENTION |
| 2 | 60 | 4586 | 4586 | AAA | AAA | PRESENT |
| | | | | | | INVENTION |
| 3 | 60 | 2293 | 2293 | AAA | AAA | PRESENT |
| | | | | | | INVENTION |
| 4 | 60 | 4586 | 4586 | AAA | AA | PRESENT |
| | | | | | | INVENTION |
| 5 | 60 | 4586 | 4586 | AAA | AA | PRESENT |
| | | | | | | INVENTION |
| 6 | 60 | 4586 | 4586 | A | AAA | PRESENT |
| | | | | | | INVENTION |
| 7 | 50 | 4586 | 5503 | AA | AAA | PRESENT |
| | | | | | | INVENTION |
| 8 | 15 | 200 | 800 | B | AAA | COMPARATIVE |
| | | | | | | EXAMPLE |

As is clear from the above results, when the apparatus for producing a functional film of the present invention was used, the etching processing can be performed more efficiently than with the production apparatus of the comparative example. In addition, when the apparatus for producing a functional film of the present invention was used, the degree of damage to the mask could be reduced, and the uniformity of etching in the in-plane distribution of the plasma electrodes was good, as compared with the production apparatus of the comparative example.

### INDUSTRIAL APPLICABILITY

The present invention can be used for an apparatus and a method for producing a functional film capable of efficiently forming a fine uneven structure at a low cost while using an etching technique.

### REFERENCE SIGNS LIST

200 functional film production apparatus
201 chamber
202 matching box
203 RF power source
204 inlet pipe
205 outlet pipe
206 etching gas introduction part
207 gas introduction pipe
208 introduction port
209 exhaust port
210 mechanical booster pump
211 rotary pump
300 plasma electrode
301 RF electrode
301A first RF electrode
301B second RF electrode
302 ground electrode
302A first ground electrode
302B second ground electrode
303 pipe
304 insulating plate-like member
1 base material
2 inorganic layer
3 metal mask
20 uneven layer
20A fine uneven structure including protruding portions of a one-step shape
20B fine uneven structure including protruding portions of a two-step shape
21 protruding portions of the first step
22 protruding portions of the second step
21B lowermost surface of protruding portions of the first step
22A uppermost surface of protruding portions of the second step
22B lowermost surface of protruding portions of the second step
100 functional film
H total average height
h average height of protruding portions of the uppermost step
5 reflectance adjustment layer
6 self-assembly promoting compound

1. An apparatus that produces a functional film having an uneven structure, comprising a plasma electrode used for etching, wherein an area of the plasma electrode is in a range of 1000 to 100000 cm².

2. The apparatus according to claim 1, wherein the etching is performed by applying a power with a frequency in a range of 0.1 kHz to 1 MHz to the plasma electrode.

3. The apparatus according to claim 1, wherein the plasma electrode includes at least two pairs of plasma electrodes.

4. The apparatus according to claim 3, wherein the at least two pairs of plasma electrodes are electrically connected in parallel.

5. The apparatus according to claim 1, further comprising a mechanism that maintains the plasma electrode at 45° C. or lower.

6. The apparatus according to claim 1, wherein a cooling solvent circulates through the plasma electrode.

7. The apparatus according to claim 1, further comprising a chamber in which the plasma electrode is disposed, wherein the chamber is uniformly filled with an etching gas.

8. The apparatus according to claim 1, further comprising a chamber in which the plasma electrode is disposed, wherein
the chamber is provided with an introduction port for introducing a gas and an exhaust port for exhausting the gas, and
the introduction port and the exhaust port are disposed at opposite positions across the plasma electrode.

9. The apparatus according to claim 1, wherein the uneven structure of the functional film has randomness without regularity.

10. The apparatus according to claim 1, further comprising a chamber in which the plasma electrode is disposed, wherein 50% or more of a surface area of an inner wall of the chamber and a member to be disposed in the chamber is coated with a film made of aluminum or calcium.

11. The apparatus according to claim 1, further comprising a chamber in which the plasma electrode is disposed, wherein a detector for detecting a concentration of a hydrogen fluoride gas is disposed in the chamber.

12. A method for producing the functional film having the uneven structure, comprising using the apparatus according claim 1.
